(19) United States
(12) Patent Application Publication
(10) Pub. No.: US 2026/0122913 A1
(43) Pub. Date: Apr. 30, 2026

(54) MAGNETORESISTIVE MEMORY DEVICE AND METHOD OF MANUFACTURING THE SAME

(71) Applicant: SAMSUNG ELECTRONICS CO., LTD., Suwon-si (KR)

(72) Inventors: Manjin Eom, Suwon-si (KR); Youngkeol Kim, Suwon-si (KR); Junghoon Bak, Suwon-si (KR); Wonhyeok Heo, Suwon-si (KR)

(21) Appl. No.: 19/003,929

(22) Filed: Dec. 27, 2024

(30) Foreign Application Priority Data
Jan. 17, 2024 (KR) 10-2024-0007642

(51) Int. Cl. H10B 61/00; H10N 50/01; H10N 50/10; H10N 50/80

(52) U.S. Cl. CPC H10B 61/10; H10N 50/01; H10N 50/10; H10N 50/80

(57) ABSTRACT

A magnetoresistive memory device includes a lower contact structure on a substrate, a data storage structure comprising a first pattern structure, a tunnel barrier pattern, and a second pattern structure, which are sequentially stacked on the lower contact structure, a first spacer structure covering a side wall of the first pattern structure, a second spacer structure apart from the first spacer structure in a vertical direction and covering a side wall of the second pattern structure, an isolation insulating layer in contact with a side wall of the tunnel barrier pattern, and a protective insulating layer covering the data storage structure, the first spacer structure, the second spacer structure, and the isolation insulating layer.

### CROSS-REFERENCE TO RELATED APPLICATION

This application is based on and claims priority under 35 U.S.C. § 119 to Korean Patent Application No. 10-2024-0007642, filed on Jan. 17, 2024, in the Korean Intellectual Property Office, the disclosure of which is incorporated by reference herein in its entirety.

### BACKGROUND

An array of research into electronic devices using magnetoresistive properties of a magnetic tunnel junction (MTJ) has been conducted. As an MTJ cell of a highly integrated magnetic random-access memory (MRAM) has been refined, refinement of lines and/or contacts included in the refined MTJ cell has been required. A wide range of research has been performed to improve the reliability of the magnetoresistive memory device while satisfying the demand for high integration and/or low power consumption.

### SUMMARY

The disclosure provides a magnetoresistive memory device having improved reliability.

The disclosure provides a method of manufacturing a magnetoresistive memory device having improved reliability.

According to an aspect of the disclosure, there is provided a magnetoresistive memory device including a lower contact structure on a substrate, a data storage structure including a first pattern structure, a tunnel barrier pattern, and a second pattern structure, which are sequentially stacked on the lower contact structure, a first spacer structure covering a side wall of the first pattern structure, a second spacer structure apart from the first spacer structure in a vertical direction and covering a side wall of the second pattern structure, an isolation insulating layer in contact with a side wall of the tunnel barrier pattern, and a protective insulating layer covering the data storage structure, the first spacer structure, the second spacer structure, and the isolation insulating layer.

According to another aspect of the disclosure, there is provided a magnetoresistive memory device including a lower contact structure on a substrate, a data storage structure including a first pattern structure, a tunnel barrier pattern, and a second pattern structure, which are sequentially stacked on the lower contact structure, a first spacer structure covering a side wall of the first pattern structure, a second spacer structure apart from the first spacer structure in a vertical direction and covering a side wall of the second pattern structure, a first conductive re-deposition layer arranged between the first pattern structure and the first spacer structure, a second conductive re-deposition layer arranged between the second pattern structure and the second spacer structure, and an insulating liner in contact with a side wall of the tunnel barrier pattern between the first conductive re-deposition layer and the second conductive re-deposition layer and covering an outer wall of the first spacer structure and an outer wall of the second spacer structure.

According to another aspect of the disclosure, there is provided a magnetoresistive memory device including a lower contact structure on a substrate, a data storage structure including a first pattern structure, a tunnel barrier pattern, and a second pattern structure, which are sequentially stacked on the lower contact structure, a first spacer structure covering a side wall of the first pattern structure, a second spacer structure apart from the first spacer structure in a vertical direction and covering a side wall of the second pattern structure, a first conductive re-deposition layer arranged between the first pattern structure and the first spacer structure, a second conductive re-deposition layer arranged between the second pattern structure and the second spacer structure, and an isolation insulating layer in contact with a side wall of the tunnel barrier pattern between the first conductive re-deposition layer and the second conductive re-deposition layer, wherein a first thickness, which is a horizontal thickness of the first spacer structure, decreases away from an upper surface of the substrate, and an outer wall of the second spacer structure includes a first portion having a positive profile in which the first portion extends such that a second thickness, which is a horizontal thickness of the second spacer structure, increases away from the upper surface of the substrate, and a second portion having a negative profile in which the second portion extends such that the second thickness of the second spacer structure decreases away from the upper surface of the substrate.

### BRIEF DESCRIPTION OF THE DRAWINGS

Embodiments will be more clearly understood from the following detailed description taken in conjunction with the accompanying drawings in which:

FIG. 1 is a circuit diagram of a memory cell of a magnetoresistive memory device according to embodiments;

FIG. 2A is a plan view of a magnetoresistive memory device according to some embodiments;

FIG. 2B is a cross-sectional view of the magnetoresistive memory device taken along line X1-X1′ of FIG. 2A;

FIG. 2C is an enlarged view of a region indicated as “EXA1” of FIG. 2B;

FIG. 2D is an enlarged view of a region indicated as “EXA2” of FIG. 2C;

FIG. 2E is an enlarged view of a region indicated as “EXA3” of FIG. 2C;

FIG. 3 is a cross-sectional view of a magnetoresistive memory device according to some embodiments and illustrates a region corresponding to the region indicated as “EXA1” of FIG. 2B;

FIG. 4 is a cross-sectional view of a magnetoresistive memory device according to some embodiments and illustrates a region corresponding to the region indicated as “EXA1” of FIG. 2B;

FIG. 5 is a cross-sectional view of a magnetoresistive memory device according to some embodiments and illustrates a region corresponding to the region indicated as “EXA1” of FIG. 2B;

FIG. 6A is a cross-sectional view of a magnetoresistive memory device according to some embodiments and illustrates a region corresponding to the region indicated as “EXA1” of FIG. 2B;

FIG. 6B is an enlarged view of a region indicated as “EXB1” of FIG. 6A;

FIG. 7 is a cross-sectional view of a magnetoresistive memory device according to some embodiments;

FIGS. 8 to 18 are views for describing, according to a process order, a method of manufacturing a magnetoresistive memory device, according to some embodiments, wherein FIGS. 7, 8, 9, 10A, 11, 12, 13, 14, 15, 16, 17A, and 18 show a region corresponding to a cross-section taken along the line X1-X1′ of FIG. 2, and FIGS. 10B and 17B are cross-sectional views of a region corresponding to the region indicated as “EXA2” of FIG. 2C; and

FIG. 19 is a cross-sectional view for describing a method of manufacturing a magnetoresistive memory device, according to some embodiments, and illustrates a region corresponding to the region indicated as “EXA2” of FIG. 2C.

### DETAILED DESCRIPTION

Hereinafter, embodiments are described in detail with reference to the accompanying drawings. For the same elements in the drawings, the same reference numerals are used, and the same descriptions are not repeated.

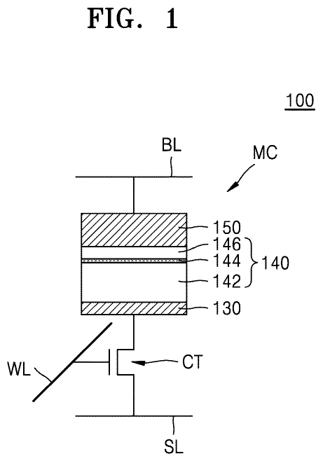

FIG. 1 is a circuit diagram of a memory cell MC of a magnetoresistive memory device 100 according to some embodiments.

According to some embodiments, the magnetoresistive memory device 100 includes the memory cell MC. The memory cell MC includes a first electrode pattern 130, a second electrode pattern 150, and a magnetic tunnel junction structure 140 between the first electrode pattern 130 and the second electrode pattern 150. The magnetic tunnel junction structure 140 may be connected to a cell transistor CT through the first electrode pattern 130.

According to some embodiments, a gate of the cell transistor CT may be connected to a word line WL. An electrode of the cell transistor CT may be connected to a bit line BL through the magnetic tunnel junction structure 140. For example, the bit line BL may be connected to the magnetic tunnel junction structure 140 through the second electrode pattern 150. The other electrode of the cell transistor CT may be connected to a source line SL.

According to some embodiments, the magnetic tunnel junction structure 140 includes a first magnetic pattern 142, a tunnel barrier pattern 144, and a second magnetic pattern 146. The tunnel barrier pattern 144 may be arranged between the first magnetic pattern 142 and the second magnetic pattern 146. An end of the first magnetic pattern 142 may be connected to the cell transistor CT through the first electrode pattern 130, and the other end of the first magnetic pattern 142 may be connected to the tunnel barrier pattern 144. An end of the second magnetic pattern 146 may be connected to the tunnel barrier pattern 144, and the other end of the second magnetic pattern 146 may be connected to the bit line BL through the second electrode pattern 150.

The magnetic tunnel junction structure 140 may be a variable resistance device which may be switched into two resistive states depending on an electrical pulse applied. For example, the magnetic tunnel junction structure 140 may perform a memory function based on a resistance difference depending on the magnetization direction alignment, by using a spin transfer torque (STT) phenomenon where a magnetic object has a varying magnetization direction depending on a current applied thereto.

For example, the first magnetic pattern 142 may have a magnetization easy axis in a direction and may have a fixed magnetization direction, and the second magnetic pattern 146 may share the magnetization easy axis and may have a magnetization direction varying depending on a condition. A resistance value of the magnetic tunnel junction structure 140 may vary depending on the magnetization directions of the first magnetic pattern 142 and the second magnetic pattern 146. For example, when the magnetization direction of the second magnetic pattern 146 and the magnetization direction of the first magnetic pattern 142 are parallel to each other, the magnetic tunnel junction structure 140 may have a first resistance value and may store data of “0.” For example, when the magnetization direction of the second magnetic pattern 146 and the magnetization direction of the first magnetic pattern 142 are antiparallel to each other, the magnetic tunnel junction structure 140 may have a second resistance value and may store data of “1.” However, the disclosure is not limited thereto. For example, the magnetization direction of the second magnetic pattern 146 may be fixed, and the first magnetic pattern 142 may have a varying magnetization direction.

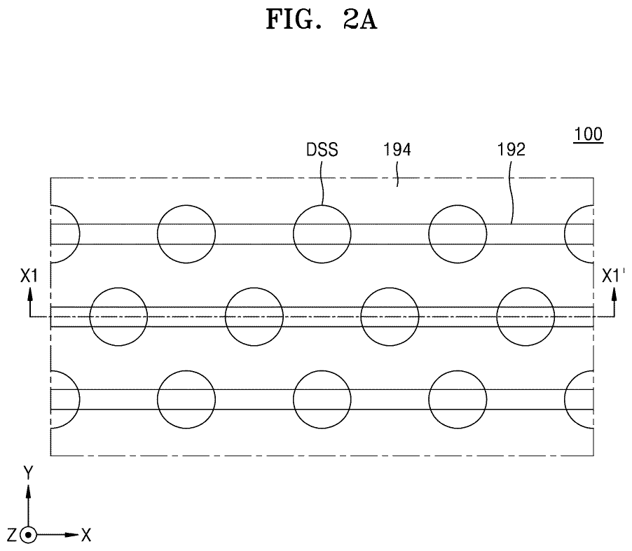

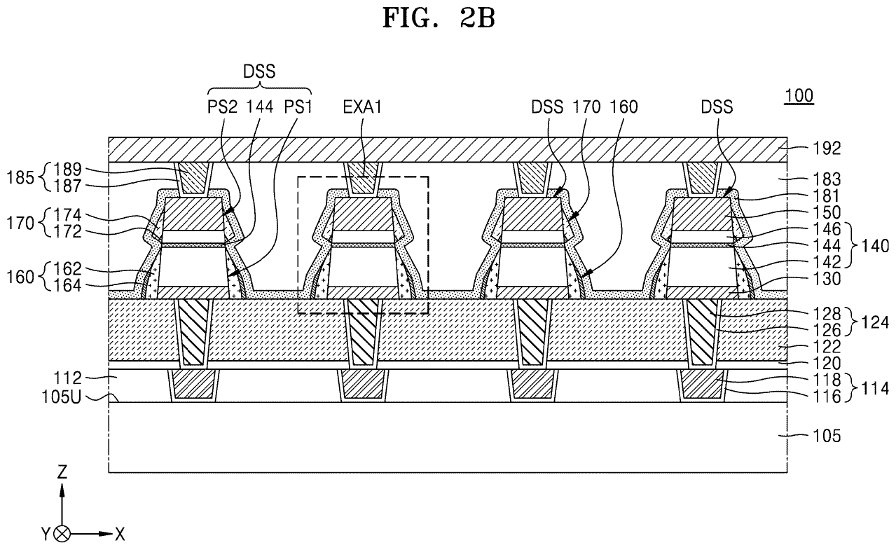

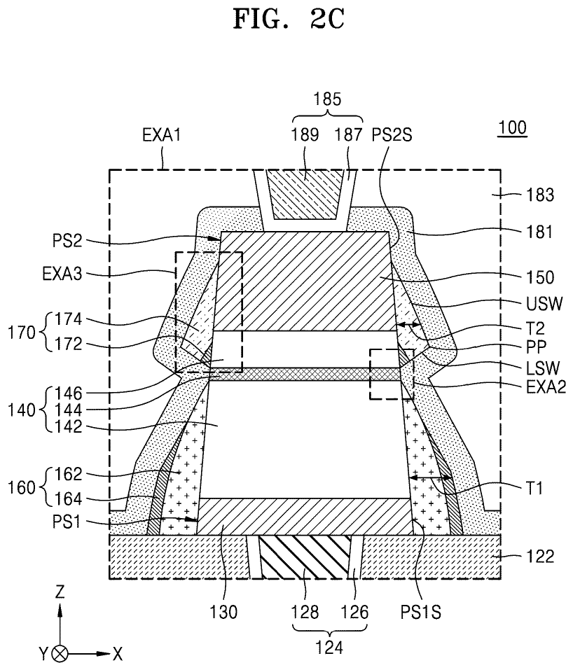

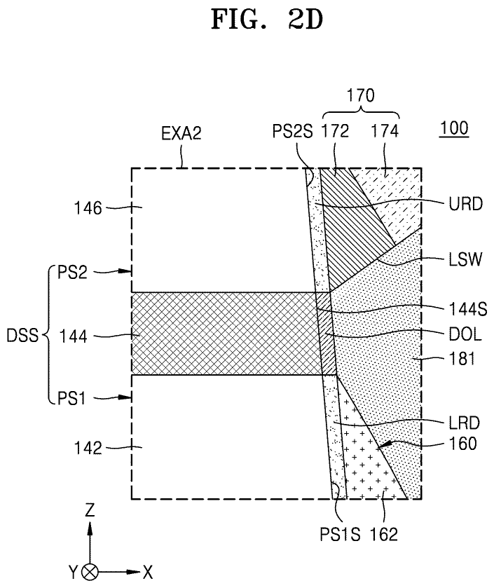

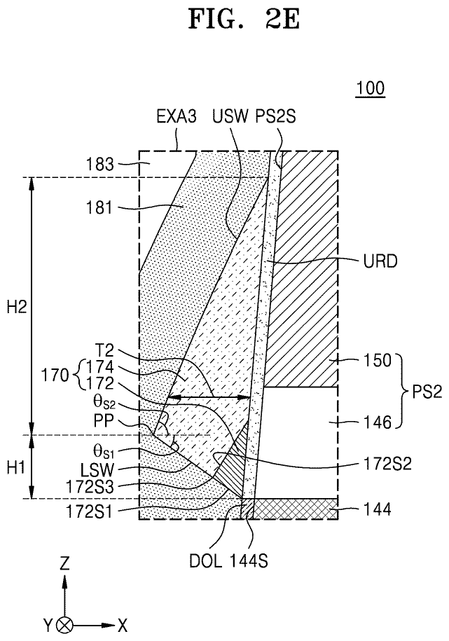

FIG. 2A is a plan view of the magnetoresistive memory device 100 according to some embodiments. FIG. 2B is a cross-sectional view of the magnetoresistive memory device 100 taken along line X1-X1′ of FIG. 2A. FIG. 2C is an enlarged view of a region indicated as “EXA1” of FIG. 2B. FIG. 2D is an enlarged view of a region indicated as “EXA2” of FIG. 2C. FIG. 2E is an enlarged view of a region indicated as “EXA3” of FIG. 2C.

Referring to FIGS. 2A to 2E, the magnetoresistive memory device 100 includes a substrate 105, a line structure 114, a first interlayer insulating layer 112, an etch stop layer 120, a plurality of lower contact structures 124, a second interlayer insulating layer 122, a plurality of data storage structures DSS, a first spacer structure 160, a second spacer structure 170, a protective insulating layer 181, a gap-fill insulating layer 183, a plurality of upper contact structures 185, and a plurality of upper conductive lines 192.

According to some embodiments, the line structure 114 may be arranged on the substrate 105, and the line structure 114 may be surrounded by the first interlayer insulating layer 112. A side wall of the line structure 114 may be in contact with the first interlayer insulating layer 112, and an upper surface of the line structure 114 may be exposed through an upper surface of the first interlayer insulating layer 112. According to some embodiments, the line structure 114 may pass through the first interlayer insulating layer 112 and may be connected to the substrate 105.

According to some embodiments, the substrate 105 may include an element semiconductor, such as Si and Ge, or a compound semiconductor, such as SiC, GaAs, InAs, and InP. The substrate 105 may include a semiconductor substrate and structures including at least one insulating layer above the semiconductor substrate or at least one conductive area. The conductive area may include a well doped with impurities or a structure doped with impurities. A device isolation area (not shown) defining a plurality of active areas may be formed in the substrate 105. The device isolation area may include an oxide layer, a nitride layer, or a combination thereof. For example, the structures may include the cell transistor CT, the word line WL, and the source line SL described with reference to FIG. 1. The line structure 114 may be electrically connected to at least some of the structures.

According to some embodiments, the first interlayer insulating layer 112 may include an oxide layer, a nitride layer, an ultra low-k (ULK) layer having an ultra-low dielectric constant K of about 2.2 to about 2.4, or a combination thereof. According to some embodiments, the first interlayer insulating layer 112 may include a tetraethylorthosilicate (TEOS) layer, a high density plasma (HDP) layer, a boro-phospho-silicate glass (BPSG) layer, a flowable chemical vapor deposition (FCVD) oxide layer, a SiON layer, a SiN layer, a SiOC layer, a SiCOH layer, or a combination thereof, but is not limited thereto. In this specification, “SiON,” “SiN,” “SiOC,” etc. denote materials including elements included in respective terms and are not chemical formulas indicating stoichiometric relationships.

According to some embodiments, the line structure 114 includes a line barrier pattern 116 and a line pattern 118. For example, the line pattern 118 may include a conductive line extending in a horizontal direction (an X direction and/or a Y direction) with respect to the substrate 105 and/or a contact extending in a vertical direction (a Z direction) with respect to the substrate 105. The line barrier pattern 116 may be arranged between the line pattern 118 and the first interlayer insulating layer 112 and between the line pattern 118 and the substrate 105. According to some embodiments, the line barrier pattern 116 may include Ti, Ta, TiN, TaN, or a combination thereof, and the line pattern 118 may include W, Al, Co, Cu, Ru, Mn, or a combination thereof. However, the line barrier pattern 116 and the line pattern 118 are not limited thereto.

According to some embodiments, the etch stop layer 120 may be arranged on the line structure 114 and the first interlayer insulating layer 112, and the second interlayer insulating layer 122 may be arranged on the etch stop layer 120. According to some embodiments, each of the plurality of lower contact structures 124 may pass though the etch stop layer 120 and the second interlayer insulating layer 122 and may be in contact with the line structure 114. According to some embodiments, the plurality of lower contact structures 124 may be arranged on the line structure 114 to be apart from each other in the horizontal direction (the X direction and/or the Y direction).

According to some embodiments, the second interlayer insulating layer 122 may include a silicon oxide layer, for example, a TEOS layer. According to some embodiments, the etch stop layer 120 may include an insulating material having an etch selectivity with respect to the second interlayer insulating layer 122. For example, the etch stop layer 120 may include a silicon boron nitride (SiBN) layer, a silicon carbonitride (SiCN) layer, a silicon nitride (SiN) layer, or a combination thereof.

According to some embodiments, each of the plurality of lower contact structures 124 includes a contact barrier pattern 126 and a contact plug 128. According to some embodiments, the contact barrier pattern 126 may cover an inner wall of a contact opening passing through the second interlayer insulating layer 122 and the etch stop layer 120 in the vertical direction (the Z direction). The contact plug 128 may fill the contact opening above the contact barrier pattern 126. According to some embodiments, the contact barrier pattern 151 may include Ti, Ta, TiN, TaN, or a combination thereof. According to some embodiments, the conductive plug 153 may include W, Co, Cu, Ru, Mn, or a combination thereof.

According to some embodiments, the plurality of data storage structures DSS may be arranged on the plurality of lower contact structures 124, respectively. As illustrated in FIG. 2A, the plurality of data storage structures DSS may be arranged to be apart from each other in the horizontal direction (the X direction and/or the Y direction). The plurality of lower contact structures 124 may extend in the vertical direction (the Z direction) between the plurality of data storage structures DSS and the line structure 114 and may connect the plurality of data storage structures DSS with the line structure 114. According to some embodiments, a lower surface of each of the plurality of data storage structures DSS may be in contact with a lower contact structure 124 corresponding thereto from among the plurality of lower contact structures 124.

According to some embodiments, a side wall of each of the plurality of data storage structures DSS may be covered by the first spacer structure 160 and the second spacer structure 170. According to some embodiments, a lower portion of each of the plurality of data storage structures DSS may be at least partially surrounded by the first spacer structure 160, and an upper portion of each of the plurality of data storage structures DSS may be at least partially surrounded by the second spacer structure 170. According to some embodiments, the first spacer structure 160 may be in contact with the second interlayer insulating layer 122 and may be arranged apart from the second spacer structure 170 in the vertical direction (the Z direction).

According to some embodiments, the protective insulating layer 181 may cover the plurality of data storage structures DSS, the first spacer structure 160, and the second spacer structure 170 on the second interlayer insulating layer 122. According to some embodiments, the protective insulating layer 181 may include a portion in contact with an upper surface of the second interlayer insulating layer 122, a portion in contact outer walls of the first spacer structure 160, and a portion in contact with outer walls of the second spacer structure 170. A portion of the side wall of each of the plurality of data storage structures DSS, the portion not being covered by the first spacer structure 160 and the second spacer structure 170, may face the protective insulating layer 181. For example, a portion of the side wall of each of the plurality of data storage structures DSS, the portion being arranged between the first spacer structure 160 and the second spacer structure 170, may face the protective insulating layer 181. For example, a portion of the side wall of each of the plurality of data storage structures DSS, the portion being adjacent to an upper surface of each of the plurality of data storage structures DSS, may not be covered by the first spacer structure 160 and may face the protective insulating layer 181. For example, the upper surface of each of the plurality of data storage structures DSS may include a portion facing the protective insulating layer 181.

According to some embodiments, on the protective insulating layer 181, the gap-fill insulating layer 183 may fill a space between the plurality of data storage structures DSS. According to some embodiments, the gap-fill insulating layer 183 may include a portion covering the upper surface of each of the plurality of data storage structures DSS.

According to some embodiments, each of the protective insulating layer 181 and the gap-fill insulating layer 183 may include oxide, nitride, and oxynitride, but the materials of the protective insulating layer 181 and the gap-fill insulating layer 183 are not limited thereto.

According to some embodiments, the plurality of upper contact structures 185 may pass through the gap-fill insulating layer 183 and the protective insulating layer 181 and may be in contact with the plurality of data storage structures DSS, respectively. According to some embodiments, each of the plurality of upper contact structures 185 includes a contact barrier pattern 187 and a contact plug 189. According to some embodiments, the contact barrier pattern 187 may pass through the gap-fill insulating layer 183 and the protective insulating layer 181 in the vertical direction (the Z direction) and may cover an inner wall of a contact opening exposing the upper surface of the corresponding data storage structure DSS from among the plurality of data storage structures DSS. The contact plug 189 may fill the contact opening on the contact barrier pattern 187. Materials of the contact barrier pattern 187 and the contact plug 189 of each of the plurality of upper contact structures 185 may be substantially the same as the materials of the contact barrier pattern 126 and the contact plug 128 of each of the plurality of lower contact structures 124 described above.

According to some embodiments, the plurality of upper conductive lines 192 may extend in a first horizontal direction (the X direction) on the gap-fill insulating layer 183. For example, the plurality of upper conductive lines 192 may be apart from each other in a second horizontal direction (the Y direction) that is perpendicular to the first horizontal direction (the X direction) and may be insulated from each other with the third interlayer insulating layer 194 therebetween. According to some embodiments, each of the plurality of upper contact structures 185 may be connected to one upper conductive line selected from among the plurality of upper conductive lines 192. Each of the plurality of data storage structures DSS may be connected to one upper conductive line selected from among the plurality of upper conductive lines 192 through the upper contact structure 185 corresponding thereto from among the plurality of upper contact structures 185. According to some embodiments, the plurality of upper conductive lines 192 may include W, Co, Cu, Ru, Ti, Ta, TiN, TaN, or a combination thereof. Each of the plurality of upper conductive lines 192 may correspond to the bit line BL described with reference to FIG. 1.

According to some embodiments, each of the plurality of data storage structures DSS includes a first pattern structure PS1, the tunnel barrier pattern 144, and a second pattern structure PS2, which are sequentially arranged on a lower contact structure 124 corresponding thereto from among the plurality of lower contact structures 124. According to some embodiments, the first pattern structure PS1 may be arranged in a space defined by an inner wall of the first spacer structure 160, and the second pattern structure PS2 may be arranged in a space defined by an inner wall of the second spacer structure 170. According to some embodiments, the first spacer structure 160 may cover at least a portion of a side wall PS1S of the first pattern structure PS1 and may surround the first pattern structure PS1 in the horizontal direction (the X direction and/or the Y direction). According to some embodiments, the second spacer structure 170 may cover at least a portion of a side wall PS2S of the second pattern structure PS2 and may surround the second pattern structure PS2 in the horizontal direction (the X direction and/or the Y direction). FIGS. 2B and 2C illustrate that the second spacer structure 170 may not cover an uppermost portion of the second pattern structure PS2. However, the disclosure is not limited thereto. For example, the second spacer structure 170 may cover an uppermost portion of the side wall PS2S of the second pattern structure PS2, the uppermost portion being adjacent to an upper surface of the second pattern structure PS2.

According to some embodiments, a first width, which is a horizontal width of the plurality of data storage structures DSS, may increase toward an upper surface 105U of the substrate 105. FIGS. 2B and 2C illustrate that the first width of the plurality of data storage structures DSS may continually increase, but the disclosure is not limited thereto. According to some embodiments, each of a second width, which is a horizontal width of the first pattern structure PS1, and a third width, which is a horizontal width of the second pattern structure PS2, may increase toward the upper surface 105U of the substrate 105, wherein the second width of an upper surface of the first pattern structure PS1 may be less than the third width of a lower surface of the second pattern structure PS2. For example, a side wall of each of the plurality of data storage structures DSS may have a recess portion between the first pattern structure PS1 and the second pattern structure PS2. According to some embodiments, the plurality of data storage structures DSS may have at least two recess portions.

According to some embodiments, the first pattern structure PS1 includes the first electrode pattern 130 arranged on the corresponding lower contact structure 124 from among the plurality of lower contact structures 124 and the first magnetic pattern 142 arranged between the first electrode pattern 130 and the tunnel barrier pattern 144. The first electrode pattern 130 may be in contact with the corresponding lower contact structure 124. A lower surface of the first magnetic pattern 142 may be in contact with the first electrode pattern 130, and an upper surface of the first magnetic pattern 142 may be in contact with the tunnel barrier pattern 144. According to some embodiments, the second pattern structure PS2 includes the second magnetic pattern 146 on the tunnel barrier pattern 144 and the second electrode pattern 150 arranged between the second magnetic pattern 146 and an upper contact structure 185 corresponding to the second pattern structure PS2 from among the plurality of upper contact structures 185. A lower surface of the second magnetic pattern 146 may be in contact with the tunnel barrier pattern 144, and an upper surface of the second magnetic pattern 146 may be in contact with the second electrode pattern 150. An upper surface of the second electrode pattern 150 may be in contact with the corresponding upper contact structure 185. According to some embodiments, the first magnetic pattern 142 and the tunnel barrier pattern 144 of the first pattern structure PS1 and the second magnetic pattern 146 of the second pattern structure PS2 may form the magnetic tunnel junction structure 140.

According to some embodiments, each of the first magnetic pattern 142 and the second magnetic pattern 146 may include at least one of Pd, Co, Pt, Fe, Ru, Ta, Ni, B, Mn, Sb, Al, Cr, Mo, Si, Cu, Ir, and an alloy thereof. For example, the alloy may include CoFe, NiFe, or CoFeB. According to some embodiments, each of the first magnetic pattern 142 and the second magnetic pattern 146 may include a single layer or multiple layers including at least two layers.

According to some embodiments, each of the first electrode pattern 130 and the second electrode pattern 150 may include a metal layer, a conductive metal oxide layer, a conductive metal nitride layer, a conductive metal oxynitride layer, or a combination thereof.

According to some embodiments, the magnetoresistive memory device 100 may include a first conductive re-deposition layer LRD covering the side wall PS1S of the first pattern structure PS1 and in contact with the side wall PS1S of the first pattern structure PS1 and a second conductive re-deposition layer URD covering the side wall PS2S of the second pattern structure PS2 and in contact with the side wall PS2S of the second pattern structure PS2. According to some embodiments, the first conductive re-deposition layer LRD may be in contact with the inner wall of the first spacer structure 160 and may include a portion between the first pattern structure PS1 and the first spacer structure 160. According to some embodiments, the second conductive re-deposition layer URD may be in contact with the inner wall of the second spacer structure 170 and may include a portion between the second pattern structure PS2 and the second spacer structure 170.

According to some embodiments, the first conductive re-deposition layer LRD may include a portion in contact with a side wall of the first magnetic pattern 142, and the second conductive re-deposition layer URD may include a portion in contact with a side wall of the second magnetic pattern 146. The first magnetic pattern 142 may face the first spacer structure 160 with the first conductive re-deposition layer LRD therebetween, and the second magnetic pattern 146 may face the second spacer structure 170 with the second conductive re-deposition layer URD therebetween.

According to some embodiments the magnetoresistive memory device 100 may include an isolation insulating layer DOL provided on a side wall 144S of the tunnel barrier pattern 144 and arranged between the first conductive re-deposition layer LRD and the second conductive re-deposition layer URD. According to some embodiments, the isolation insulating layer DOL may be in contact with at least a portion of the side wall 144S of the tunnel barrier pattern 144. According to some embodiments, the first conductive re-deposition layer LRD may be apart from the second conductive re-deposition layer URD in the vertical direction (the Z direction) with the isolation insulating layer DOL therebetween. According to some embodiments, an inner wall of the isolation insulating layer DOL may be in contact with the side wall 144S of the tunnel barrier pattern 144, and an outer wall of the isolation insulating layer DOL may be in contact with the protective insulating layer 181. The protective insulating layer 181 may face the side wall 144S of the tunnel barrier pattern 144 through a space between the first spacer structure 160 and the second spacer structure 170 and may be apart from the side wall 144S of the tunnel barrier pattern 144 with the isolation insulating layer DOL therebetween. According to some embodiments, the isolation insulating layer DOL may horizontally surround the side wall 144S of the tunnel barrier pattern 144, and the tunnel barrier pattern 144 may be arranged in a space defined by the inner wall of the isolation insulating layer DOL. For example, in a plan view, the isolation insulating layer DOL may have a ring shape.

FIG. 2D illustrates that a lower surface of the isolation insulating layer DOL may be located on the same vertical level as an upper surface of the first pattern structure PS1, and an upper surface of the isolation insulating layer DOL may be located on the same vertical level as a lower surface of the second pattern structure PS2. However, the disclosure is not limited thereto. According to some embodiments, the lower surface of the isolation insulating layer DOL may be located at a lower vertical level than the upper surface of the first pattern structure PS1, and the inner wall of the isolation insulating layer DOL may include a portion in contact with a side wall of the first pattern structure PS1. According to some embodiments, the upper surface of the isolation insulating layer DOL may be located at a higher vertical level than the lower surface of the second pattern structure PS2, and the inner wall of the isolation insulating layer DOL may include a portion in contact with the side wall PS2S of the second pattern structure PS2. According to some embodiments, the isolation insulating layer DOL may cover a portion of the side wall 144S of the tunnel barrier pattern 144, unlike the illustration of FIG. 2D. For example, the first conductive re-deposition layer LRD and/or the second conductive re-deposition layer URD may include a portion in contact with the side wall 144S of the tunnel barrier pattern 144. However, also in this case, the first conductive re-deposition layer LRD and the second conductive re-deposition layer URD may be spaced apart from each other with the isolation insulating layer DOL therebetween and may not be in contact with each other. In this specification, the “vertical level” indicates a distance from the upper surface 105U of the substrate 105 in the vertical direction (the Z direction or a −Z direction).

According to some embodiments, an uppermost surface of the first spacer structure 160 may be located at substantially the same vertical level as or a lower vertical level than the upper surface of the first pattern structure PS1, for example, the upper surface of the first magnetic pattern 142. According to some embodiments, a lowermost surface of the second spacer structure 170 may be located at substantially the same vertical level as or a higher vertical level than the lower surface of the second pattern structure PS2, for example, the lower surface of the second magnetic pattern 146.

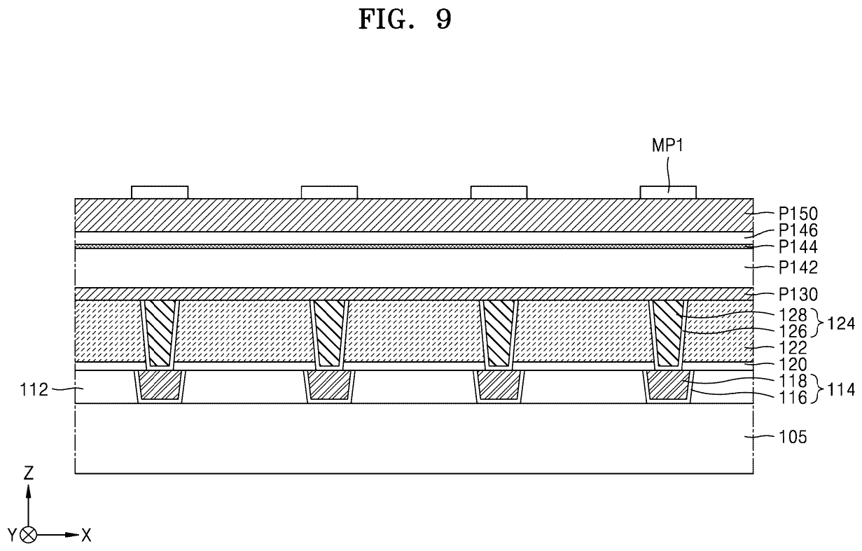

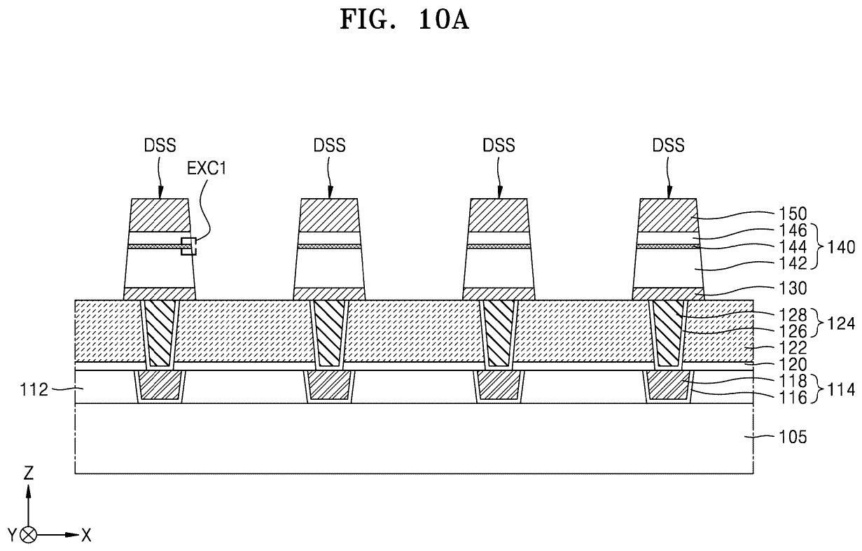

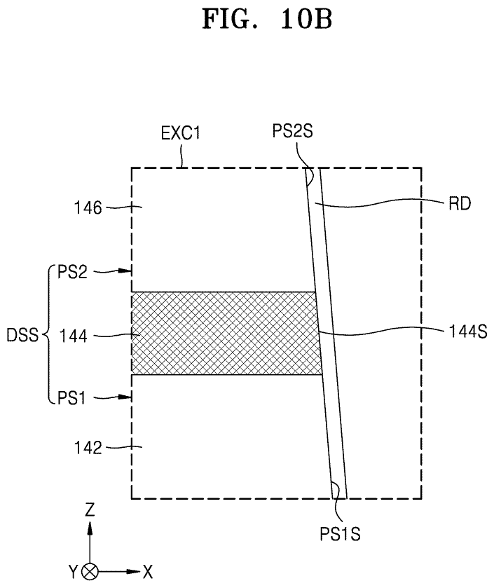

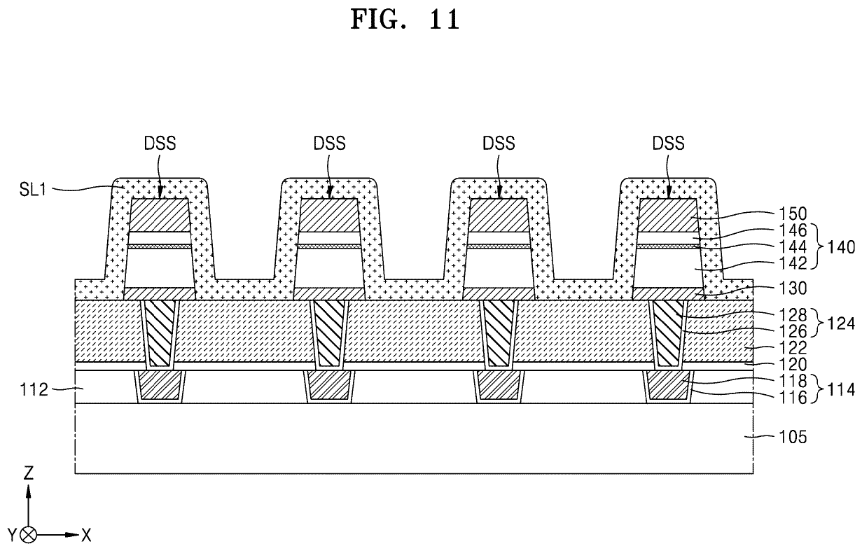

As described below with reference to FIGS. 9, 10A, and 10B, in an etch process for forming the plurality of data storage structures DSS, a conductive re-deposition layer RD may be formed on an exposed surface of the plurality of data storage structures DSS. The conductive re-deposition layer RD may cover the side wall of the first magnetic pattern 142, the side wall 144S of the tunnel barrier pattern 144, and the side wall of the second magnetic pattern 146 altogether. The magnetoresistive memory device 100 according to some embodiments may include the isolation insulating layer DOL formed by a subsequent process, and thus, may prevent a short circuit between the first magnetic pattern 142 and the second magnetic pattern 146. Thus, a resistance difference between the first magnetic pattern 142 and the second magnetic pattern 146 may be maintained to improve the reliability of the magnetoresistive memory device 100.

According to some embodiments, the first spacer structure 160 may have a first thickness T1, which is a horizontal distance between the inner wall thereof in contact with the side wall PS1S of the first pattern structure PS1 and an outer wall thereof in contact with the protective insulating layer 181. According to some embodiments, the first thickness T1 may increase toward the upper surface 105U of the substrate 105. For example, the first thickness T1 of the first spacer structure 160 may decrease toward an increased vertical level. In this specification, a horizontal distance between an inner wall and an outer wall of a spacer structure may be referred to as a horizontal thickness of the spacer structure.

According to some embodiments, the first spacer structure 160 includes a first lower spacer 162 in contact with the first conductive re-deposition layer LRD on the side wall PS1S of the first pattern structure PS1 and a second lower spacer 164 provided on an outer wall of the first lower spacer 162. According to some embodiments, the second lower spacer 164 may be spaced apart from the side wall PS1S of the first pattern structure PS1 with the first lower spacer 162 and the first conductive re-deposition layer LRD therebetween. According to some embodiments, the second lower spacer 164 may cover a lower portion of the outer wall of the first lower spacer 162, while not covering an upper portion of the outer wall of the first lower spacer 162. For example, the upper portion of the outer wall of the first lower spacer 162 may be in contact with the protective insulating layer 181, and the lower portion of the outer wall of the first lower spacer 162 may be spaced apart from the protective insulating layer 181 with the second lower spacer 164 therebetween.

According to some embodiments, the first lower spacer 162 and the second lower spacer 164 may include different materials from each other. Here, the different materials may refer to the same type of element compositions having different atom ratios from each other. According to some embodiments, each of the first lower spacer 162 and the second lower spacer 164 may include silicon oxide, silicon nitride, silicon oxynitride, or a combination thereof. According to some embodiments, the first lower spacer 162 and the second lower spacer 164 may include the same types of element compositions as each other, but an atom ratio of each of the element compositions of the first lower spacer 162 and the second lowers spacer 164 may be different from each other. For example, each of the first lower spacer 162 and the second lower spacer 164 may include silicon nitride. However, a first ratio, which is a ratio of a nitrogen atom to a silicon atom in the first lower spacer 162, may be different from a second ratio, which is a ratio of the nitrogen atom to the silicon atom in the second lower spacer 164.

According to some embodiments, the second spacer structure 170 may have an inner wall in contact with the side wall PS2S of the second pattern structure PS2 and an outer wall in contact with the protective insulating layer 181. The second spacer structure 170 may have a second thickness T2, which is a horizontal distance between the inner wall and the outer wall of the second spacer structure 170.

According to some embodiments, the outer wall of the second spacer structure 170 includes a first portion LSW having a positive profile in which the second thickness T2 of the second spacer structure 170 increases as the distance from the upper surface 105U of the substrate 105 becomes greater, and includes a second portion USW extending from the first portion LSW and having a negative profile in which the second thickness T2 of the second spacer structure 170 decreases as the distance from the upper surface 105U of the substrate 105 becomes greater. For example, the first portion LSW may be located at a lower vertical level than the second portion USW. According to some embodiments, the outer wall of the second spacer structure 170 includes a third portion PP at which the first portion LSW and the second portion USW meet each other. For example, the second thickness T2 of the second spacer structure 170 may be the greatest at the third portion PP.

According to some embodiments, a first height H1, which is a length of the first portion LSW in the vertical direction (the Z direction), may be less than a second height H2, which is a length of the second portion USW in the vertical direction (the Z direction). According to some embodiments, the first portion LSW may have a first angle θ_{S1} with respect to a first surface that is parallel with the upper surface 105U of the substrate 105, and the second portion USW may have a second angle θ_{S2} with respect to the first surface. According to some embodiments, the first angle θ_{S1} may be less than the second angle θ_{S2}. According to some embodiments, the first angle θ_{S1} may be less than 60°, for example, less than 45°.

According to some embodiments, the second spacer structure 170 includes a first upper spacer 172 and a second upper spacer 174 provided on the side wall PS2S of the second pattern structure PS2. According to some embodiments, each of the first upper spacer 172 and the second upper spacer 174 may be in contact with the second conductive re-deposition layer URD on the side wall PS2S of the second pattern structure PS2. According to some embodiments, the first upper spacer 172 may be in contact with a first portion of the second conductive re-deposition layer URD, the first portion being relatively close to the isolation insulating layer DOL, and the second upper spacer 174 may be in contact with a second portion of the second conductive re-deposition layer URD, the second portion being farther from the isolation insulating layer DOL than the first portion. For example, the first portion of the second conductive re-deposition layer URD may be located at a lower vertical level than the second portion of the second conductive re-deposition layer URD.

According to some embodiments, the first upper spacer 172 may have substantially the same shape as the second spacer structure 170. For example, an outer wall of the first upper spacer 172 includes a first portion 172S1 having a positive profile in which a horizontal thickness of the first upper spacer 172 increases as the distance from the upper surface 105U of the substrate 105 becomes greater, and a second portion 172S2 extending from the first portion 172S1 and having a negative profile in which the horizontal thickness of the first upper spacer 172 decreases as the distance from the upper surface 105U of the substrate 105 becomes greater. For example, the horizontal thickness of the first upper spacer 172 may be the greatest at a third portion 172S3 of the outer wall of the first upper spacer 172 at which the first portion 172S1 and the second portion 172S2 meet each other.

According to some embodiments, the second upper spacer 174 may be provided on the side wall PS2S of the second pattern structure PS2 and may be arranged to cover the second portion 172S2 of the outer wall of the first upper spacer 172. According to some embodiments, the first upper spacer 172 may overlap the second upper spacer 174 in the vertical direction (the Z direction). According to some embodiments, the second upper spacer 174 may be in contact with the second portion 172S2 of the outer wall of the first upper spacer 172, but may not be in contact with the first portion 172S1. According to some embodiments, a lowermost surface of the second upper spacer 174 may be located at a higher vertical level than a lowermost surface of the first upper spacer 172. For example, the lowermost surface of the second upper spacer 174 may be arranged to be farther from the upper surface 105U of the substrate 105 than the lowermost surface of the first upper spacer 172.

According to some embodiments, the third portion 172S3 of the first upper spacer 172 may be located at a lower vertical level than the third portion PP of the second spacer structure 170. For example, the third portion PP of the second spacer structure 170, at which the second thickness T2 of the second spacer structure 170 is the greatest, may be arranged to be farther from the upper surface 105U of the substrate 105 than the third portion 172S3 of the first upper spacer 172, at which the horizontal thickness of the first upper spacer 172 is the greatest.

According to some embodiments, the first portion LSW of the outer wall of the second spacer structure 170, the first portion LSW having the positive profile, includes the first portion 172S1 of the outer wall of the first upper spacer 172 and a portion of the outer wall of the second upper spacer 174. According to some embodiments, the second portion USW of the outer wall of the second spacer structure 170, the second portion having the negative profile, includes another portion of the outer wall of the second upper spacer 174. The first portion LSW and the second portion USW of the outer wall of the second spacer structure 170 may be in contact with the protective insulating layer 181. For example, the first portion 172S1 of the outer wall of the first upper spacer 172 may be in contact with the protective insulating layer 181.

According to some embodiments, the first upper spacer 172 and the second upper spacer 174 may include different materials from each other. Here, the different materials may refer to the same type of element compositions having different atom ratios from each other. According to some embodiments, each of the first upper spacer 172 and the second upper spacer 174 may include silicon oxide, silicon nitride, silicon oxynitride, or a combination thereof. According to some embodiments, the first upper spacer 172 may include silicon oxide, silicon nitride, silicon oxynitride, or a combination thereof, and the second upper spacer 174 may include metal or metal oxide. For example, the second upper spacer 174 may include, but is not limited to, metal such as Al, Ti, Ta, La, Zr, or Hf and metal oxide such as AlO, TiO, TaO, LaO, LaAlO, ZrO, ZrSiO, ZrON, ZrSiON, HfO, HfSIO, HfON, or HfSiON.

The magnetoresistive memory device 100 according to some embodiments may be formed through a space between the first spacer structure 160 and the second spacer structure 170 and may include some layers of the magnetic tunnel junction structure 140, for example, the isolation insulating layer DOL in contact with the side wall 144S of the tunnel barrier pattern 144. The isolation insulating layer DOL may be arranged between the first conductive re-deposition layer LRD and the second conductive re-deposition layer URD formed on a surface of the data storage structure DSS and may prevent the occurrence of an electrical short circuit between the first magnetic pattern 142 and the second magnetic pattern 146. Also, the first spacer structure 160 may be arranged on a side wall of the first magnetic pattern 142 and the second spacer structure 170 may be arranged on a side wall of the second magnetic pattern 146. Thus, it is possible to prevent deterioration of the reliability of the magnetoresistive memory device 100, which may be caused by the penetration of an undesired material, for example, oxygen, into the first magnetic pattern 142 and the second magnetic pattern 146 in the manufacturing process of the magnetoresistive memory device 100.

It is described above that the first pattern structure PS1 and the second pattern structure PS2 are separated from each other with respect to the tunnel barrier pattern 144 and the isolation insulating layer DOL may be formed on the side wall 144S of the tunnel barrier pattern 144. However, the disclosure is not limited thereto. For example, the isolation insulating layer DOL may be formed on a side wall of another layer, for which it is necessary to prevent a short circuit, which could be generated through a conductive re-deposition layer.

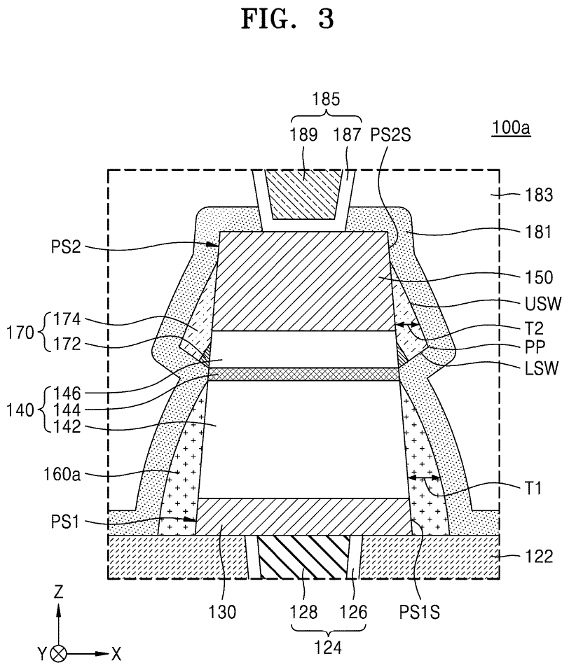

FIG. 3 is a cross-sectional view of a magnetoresistive memory device 100a according to some embodiments, the cross-sectional view illustrating a region corresponding to the region indicated as “EXA1” of FIG. 2B. In FIG. 3, the same reference numerals as the reference numerals in FIGS. 1 to 2E refer to the same members as the members in FIGS. 1 to 2E, and their descriptions are omitted here.

Referring to FIG. 3, the magnetoresistive memory device 100a may have substantially the same structure as the magnetoresistive memory device 100 described with reference to FIGS. 1 to 2E. However, the magnetoresistive memory device 100a includes a first spacer structure 160a, rather than the first spacer structure 160 of the magnetoresistive memory device 100.

According to some embodiments, the first spacer structure 160a may have substantially the same shape as the first spacer structure 160 described with reference to FIGS. 1 to 2E. For example, the first spacer structure 160a may have an inner wall facing the side wall PS1S of the first pattern structure PS1 and an outer wall in contact with the protective insulating layer 181. For example, the protective insulating layer 181 may be spaced apart from the first pattern structure PS1 with the first spacer structure 160a and the first conductive re-deposition layer LRD (see FIG. 2D) therebetween. For example, a first thickness T1, which is a horizontal width of the first spacer structure 160a, may increase toward the upper surface 105U of the substrate 105.

According to some embodiments, the first spacer structure 160a may include a single layer. According to some embodiments, the first spacer structure 160a may include silicon oxide, silicon nitride, or a combination thereof.

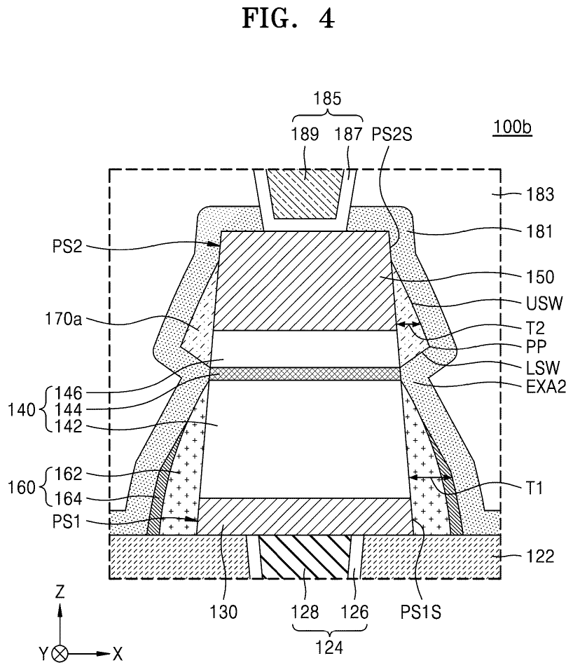

FIG. 4 is a cross-sectional view of a magnetoresistive memory device 100b according to some embodiments, the cross-sectional view illustrating a region corresponding to the region indicated as “EXA1” of FIG. 2B. In FIG. 4, the same reference numerals as the reference numerals in FIGS. 1 to 2E refer to the same members as the members in FIGS. 1 to 2E, and their descriptions are omitted here.

Referring to FIG. 4, the magnetoresistive memory device 100b may have substantially the same structure as the magnetoresistive memory device 100 described with reference to FIGS. 1 to 2E. However, the magnetoresistive memory device 100b includes a second spacer structure 170a, rather than the second spacer structure 170 of the magnetoresistive memory device 100.

According to some embodiments, the second spacer structure 170a may have substantially the same shape as the second spacer structure 170 described with reference to FIGS. 1 to 2E. For example, the second spacer structure 170a may have an inner wall facing the side wall PS2S of the second pattern structure PS2 and an outer wall in contact with the protective insulating layer 181. For example, the outer wall of the second spacer structure 170a may include a first portion LSW having a positive profile in which a second thickness T2 of the second spacer structure 170a increases away from the upper surface 105U of the substrate 105 and a second portion USW extending from the first portion LSW and having a negative profile in which the second thickness T2 of the second spacer structure 170a decreases away from the upper surface 105U of the substrate 105. For example, the second spacer structure 170a may include a third portion PP at which the first portion LSW and the second portion USW meet each other, and the second thickness T2, which is a horizontal thickness of the second spacer structure 170a, may be the greatest at the third portion PP.

According to some embodiments, the second spacer structure 170a may include a single layer. According to some embodiments, the second spacer structure 170a may include silicon oxide, silicon nitride, or a combination thereof. According to some embodiments, the second spacer structure 170a may include metal or metal oxide, and examples of the detailed materials may be substantially the same as described with respect to the second upper spacer 174 described with reference to FIGS. 1 to 2E.

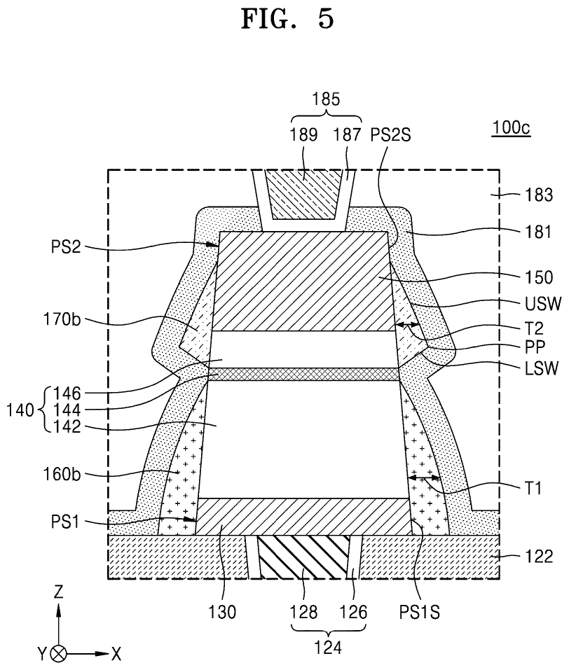

FIG. 5 is a cross-sectional view of a magnetoresistive memory device 100c according to some embodiments, the cross-sectional view illustrating a region corresponding to the region indicated as “EXA1” of FIG. 2B. In FIG. 5, the same reference numerals as the reference numerals in FIGS. 1 to 4 refer to the same members as the members in FIGS. 1 to 4, and their descriptions are omitted here.

Referring to FIG. 5, the magnetoresistive memory device 100c may have substantially the same structure as the magnetoresistive memory device 100 described with reference to FIGS. 1 to 2E. However, the magnetoresistive memory device 100c may include the first spacer structure 160a, rather than the first spacer structure 160 of the magnetoresistive memory device 100, and the second spacer structure 170a, rather than the second spacer structure 170 of the magnetoresistive memory device 100.

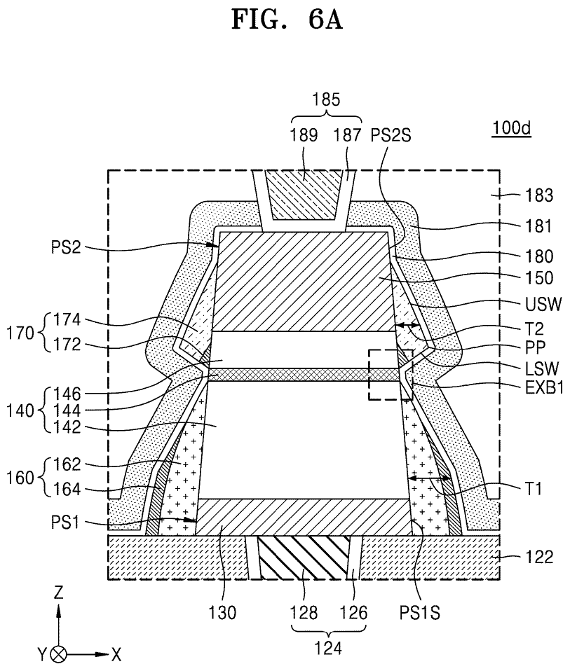

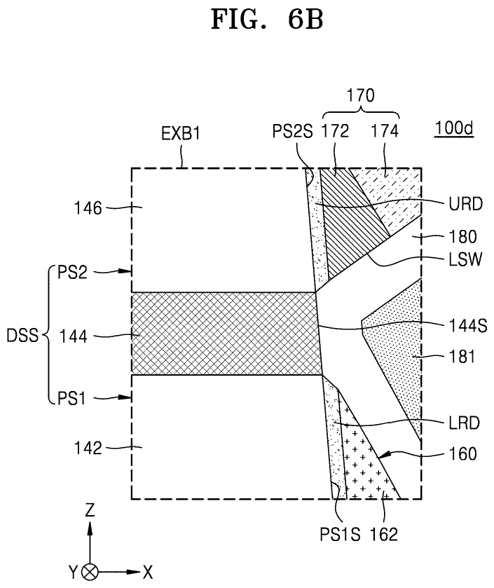

FIG. 6A is a cross-sectional view of a magnetoresistive memory device 100d according to some embodiments, the cross-sectional view illustrating a region corresponding to the region indicated as “EXA1” of FIG. 2B. FIG. 6B is an enlarged view of a region indicated as “EXB1” of FIG. 6A. In FIGS. 6A and 6B, the same reference numerals as the reference numerals in FIGS. 1 to 2E refer to the same members as the members in FIGS. 1 to 2E, and their descriptions are omitted here.

Referring to FIGS. 6A and 6B, the magnetoresistive memory device 100d may have substantially the same structure as the magnetoresistive memory device 100 described with reference to FIGS. 1 to 2E. However, the magnetoresistive memory device 100d may include an insulating liner 180 in contact with the side wall 144S of the tunnel barrier pattern 144, rather than the isolation insulating layer DOL.

According to some embodiments, the magnetoresistive memory device 100d may further include the insulating liner 180 covering the plurality of data storage structures DSS, the first spacer structure 160, and the second spacer structure 170 on the second interlayer insulating layer 122. For example, the insulating liner 180 may include portions in contact with outer walls of the first spacer structure 160 and portions in contact with outer walls of the second spacer structure 170. For example, the insulating liner 180 may cover portions of side walls of the plurality of data storage structures DSS, the portions not being covered by the first and second spacer structures 160 and 170 and being exposed, and upper surfaces of the side walls of the plurality of data storage structures DSS. According to some embodiments, the protective insulating layer 181 may cover the plurality of data storage structures DSS, the first spacer structure 160, and the second spacer structure 170 on the insulating liner 180. For example, the insulating liner 180 may include a portion arranged between the first spacer structure 160 and the protective insulating layer 181 and a portion arranged between the second spacer structure 170 and the protective insulating layer 181.

According to some embodiments, the insulating liner 180 may be in contact with the side wall 144S of the tunnel barrier pattern 144 through a space between the first spacer structure 160 and the second spacer structure 170. For example, the side wall 144S of the tunnel barrier pattern 144 may face the protective insulating layer 181 with the insulating liner 180 therebetween.

According to some embodiments, the insulating liner 180 may be arranged between the first conductive re-deposition layer LRD and the second conductive re-deposition layer URD and may prevent an electrical short circuit between the first magnetic pattern 142 and the second magnetic pattern 146. For example, the first conductive re-deposition layer LRD may be spaced apart from the second conductive re-deposition layer URD with the insulating liner 180 therebetween.

According to some embodiments, the insulating liner 180 may include oxide, nitride, or a combination thereof. For example, the insulating liner 180 may include silicon oxide.

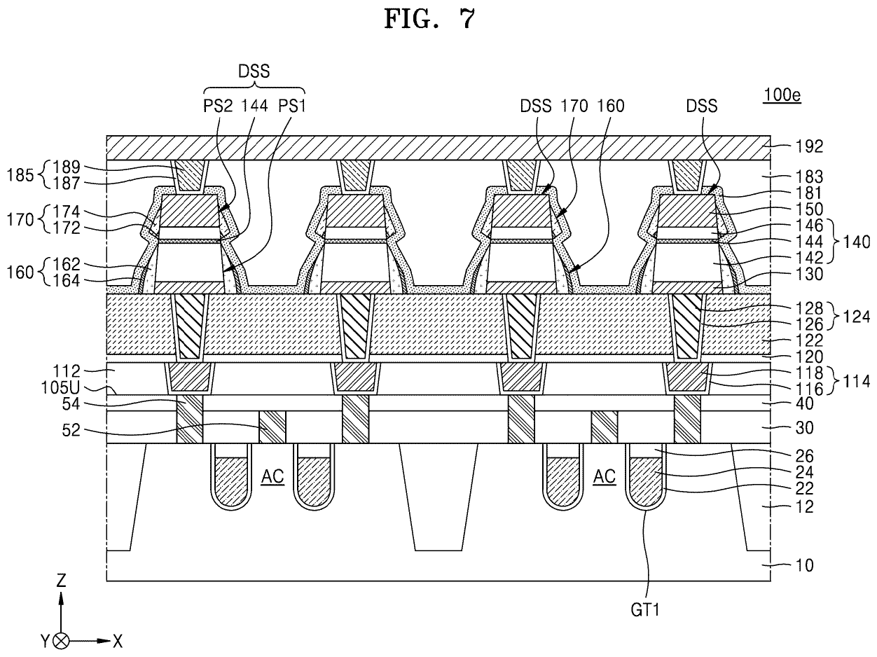

FIG. 7 is a cross-sectional view of a magnetoresistive memory device 100e according to some embodiments. In FIG. 7, the same reference numerals as the reference numerals in FIGS. 1 to 2E refer to the same members as the members in FIGS. 1 to 2E and their descriptions are omitted here.

Referring to FIG. 7, the magnetoresistive memory device 100e may have substantially the same structure as the magnetoresistive memory device 100 described with reference to FIGS. 1 to 2E. However, the magnetoresistive memory device 100e may include a substrate 10, rather than the substrate 105 of the magnetoresistive memory device 100, and transistors TR, a source line 52, and a lower contact 54 connected to the line structure 114.

According to some embodiments, the magnetoresistive memory device 100e includes the substrate 10 including an active area AC defined by a device isolation layer 12 and the transistors TR formed on the substrate 10.

According to some embodiments, the substrate 10 may include a semiconductor wafer. According to some embodiments, the substrate 10 may include a semiconductor element, such as Si and Ge, or a compound semiconductor, such as SiC, GaAs, InAs, and InP. According to some embodiments, the substrate 10 may have a silicon-on-insulator (SOI) structure. The substrate 10 may include a conductive area, for example, a well doped with impurities or a structure doped with impurities. According to some embodiments, the device isolation layer 12 may include a silicon oxide layer, but is not limited thereto.

According to some embodiments, a gate trench GT1 may be formed in the active area AC. According to some embodiments, the magnetoresistive memory device 100e includes a gate dielectric layer 22 covering an inner wall of the gate trench GT1, a gate line 24 arranged on the gate dielectric layer 22 and partially filling an inner portion of the gate trench GT1, and a capping insulating layer 26 filling a remaining portion of the gate trench GT1 on the gate line 24. The gate line 24 may correspond to the word line WL of the magnetoresistive memory device 100 described with reference to FIG. 1.

According to some embodiments, the gate dielectric layer 22 may include at least one selected from among silicon oxide, silicon nitride, silicon oxynitride, oxide/nitride/oxide (ONO), and a high-dielectric layer having a higher dielectric constant than silicon oxide. For example, the high-dielectric layer may include at least one selected from among HfO, HfSiO, HfON, HfSiON, and ZrO, but the material of the high-dielectric layer is not limited to the examples described above. According to some embodiments, the gate line 24 may include Ti, TiN, Ta, TaN, W, WN, TiSiN, WSiN, or a combination thereof. According to some embodiments, the capping insulating layer 26 may include a silicon oxide layer, a silicon nitride layer, a silicon oxynitride layer, or a combination thereof.

According to some embodiments, a first lower insulating layer 30 and a second lower insulating layer 40 may be sequentially stacked on the substrate 10 and the device isolation layer 12. According to some embodiments, the magnetoresistive memory device 100e includes the source line 52 passing through the first lower insulating layer 30 and in contact with a source area formed in a portion of the active area AC. For example, the source line 52 may extend long in the source area in the second horizontal direction (the Y direction). According to some embodiments, the magnetoresistive memory device 100e includes the lower contact 54 passing through the first lower insulating layer 30 and the second lower insulating layer 40 and in contact with a drain area formed in another portion of the active area AC. According to some embodiments, an end of the lower contact 54 in the vertical direction (the Z direction) may be connected to the drain area, and the other end may be connected to the line structure 114. According to some embodiments, the source line 52 and the lower contact 54 may be insulated from each other by the first lower insulating layer 30 and the second lower insulating layer 40.

According to some embodiments, each of the first lower insulating layer 30 and the second lower insulating layer 40 may include an oxide layer, a nitride layer, or a combination thereof. According to some embodiments, each of the source line 52 and the lower contact 54 may include metal, conductive metal nitride, or a combination thereof.

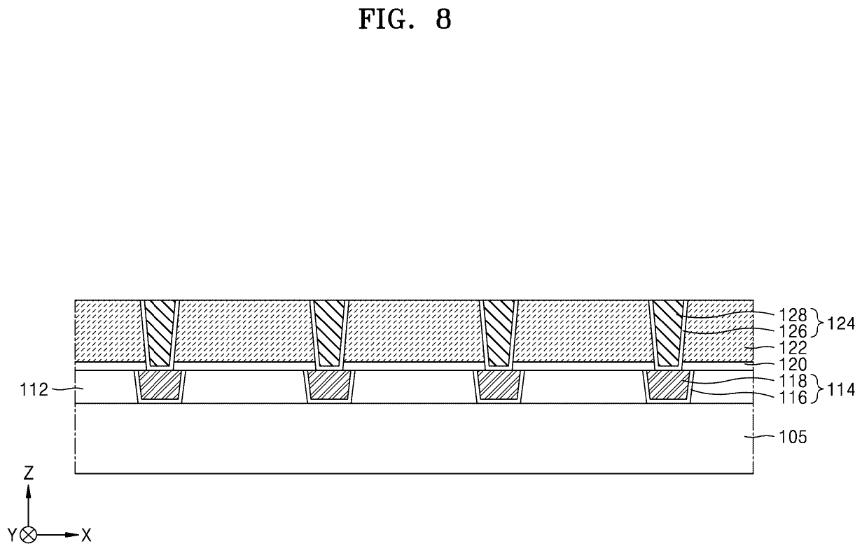

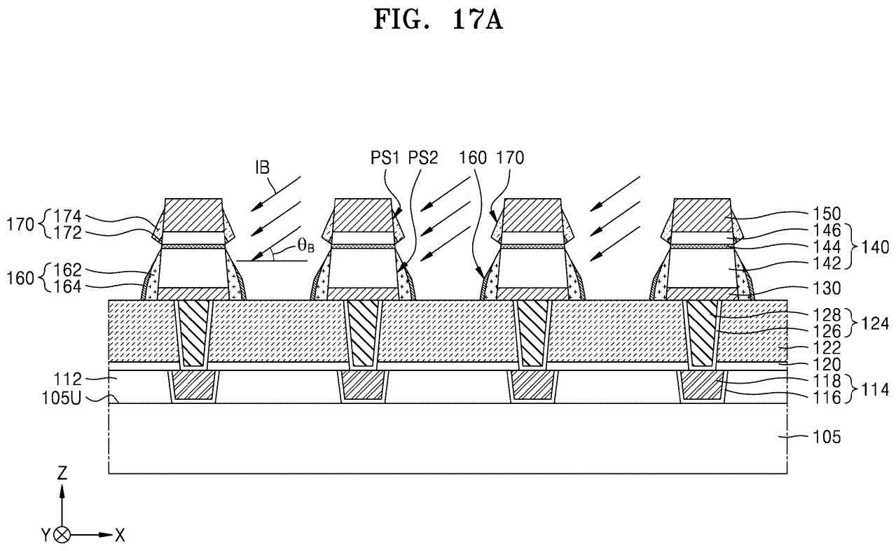

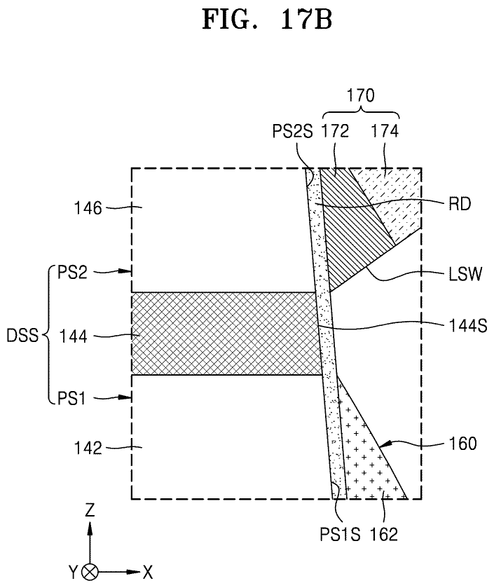

FIGS. 8 to 18 are views for describing, according to a process order, a method of manufacturing a magnetoresistive memory device, according to some embodiments, wherein FIGS. 7, 8, 9, 10A, 11, 12, 13, 14, 15, 16, 17A, and 18 show a region corresponding to a cross-section taken along the line X1-X1′ of FIG. 2, and FIGS. 10B and 17B are cross-sectional views of a region corresponding to the region indicated as “EXA2” of FIG. 2C. Hereinafter, a method of manufacturing the magnetoresistive memory device 100 described with reference to FIGS. 1 to 2E, is described by referring to FIGS. 8 to 18. In FIGS. 8 to 18, the same reference numerals as the reference numerals in FIGS. 1 to 2E refer to the same members as the members in FIGS. 1 to 2E and their descriptions are not repeatedly given here.

Referring to FIG. 8, the line structure 114 may be formed on the substrate 105. According to some embodiments, the first interlayer insulating layer 112 having a line opening may be formed on the substrate 105, and the line structure 114 may be formed by filling the line opening with the line barrier pattern 116 and the line pattern 118.

Thereafter, the etch stop layer 120 covering the first interlayer insulating layer 112 and the line structure 114 may be formed, and the second interlayer insulating layer 122 may be formed on the etch stop layer 120. According to some embodiments, the second interlayer insulating layer 122 may include a silicon oxide layer, for example, a TEOS layer. Thereafter, a mask pattern (not shown) exposing a portion of the second interlayer insulating layer 122 may be formed, and a portion of the second interlayer insulating layer 122 and a portion of the etch stop layer 120 may be removed by using the mask pattern as an etch mask to form a plurality of first contact openings. For example, the mask pattern may include a photomask layer. Thereafter, the contact barrier pattern 126 and the contact plug 128 filling each of the plurality of first contact openings may be formed to form the plurality of lower contact structures 124.

Referring to FIG. 9, with respect to a resultant structure of FIG. 8, a first electrode layer P130, a first magnetic layer P142, a tunnel barrier layer P144, a second magnetic layer P146, and a second electrode layer P150 may be sequentially formed on the second interlayer insulating layer 122 and the plurality of lower contact structures 124. Thereafter, a mask pattern MP1 exposing a portion of the second electrode layer P150 may be formed. For example, the mask pattern MP1 may include silicon nitride, silicon oxynitride, or a photoresist layer, but is not limited thereto.

Referring to FIGS. 10A and 10B, with respect to a resultant structure of FIG. 9, a portion of each of the first electrode layer P130, the first magnetic layer P142, the tunnel barrier layer P144, the second magnetic layer P146, and the second electrode layer P150 may be removed by using the mask pattern MP1 as an etch mask, in order to form the plurality of data storage structures DSS each including the first electrode pattern 130, the first magnetic pattern 142, the tunnel barrier pattern 144, and the second magnetic pattern 146.

According to some embodiments, an etch process may include a reactive ion etch (RIE) process using an etching gas and/or an ion beam etch (IBE) process using irradiation of ion beams. According to some embodiments, the etching gas of the RIE process may include HF and/or NH₃. According to some embodiments, the IBE process may include an Ar ion sputtering method.

According to some embodiments, the first magnetic layer P142 and the second magnetic layer P146 from among the etch object layers may include a magnetic material, and thus, etch by-products generated during the etch process may be re-deposited on surfaces of the plurality of data storage structures DSS to form the conductive re-deposition layer RD. The conductive re-deposition layer RD may cover the side wall PS1S of the first pattern structure PS1, the side wall 144S of the tunnel barrier pattern 144, and the side wall PS2S of the second pattern structure PS2. For example, the conductive re-deposition layer RD may cover the side wall of the first magnetic pattern 142, the side wall 144S of the tunnel barrier pattern 144, and the side wall of the second magnetic pattern 146 altogether and may be in contact with them. The conductive re-deposition layer RD may cause an electrical short circuit phenomenon between the first magnetic pattern 142 and the second magnetic pattern 146 to cause defects of a magnetoresistive memory device. In a subsequent process, the electrical short circuit between the first magnetic pattern 142 and the second magnetic pattern 146 may be prevented by oxidizing or removing, by using the first spacer structure 160 and the second spacer structure 170, some areas of a portion of the conductive re-deposition layer RD, the portion being subject to electrical insulation, for example, a portion of the conductive re-deposition layer RD, the portion being arranged on the side wall 144S of the tunnel barrier pattern 144.

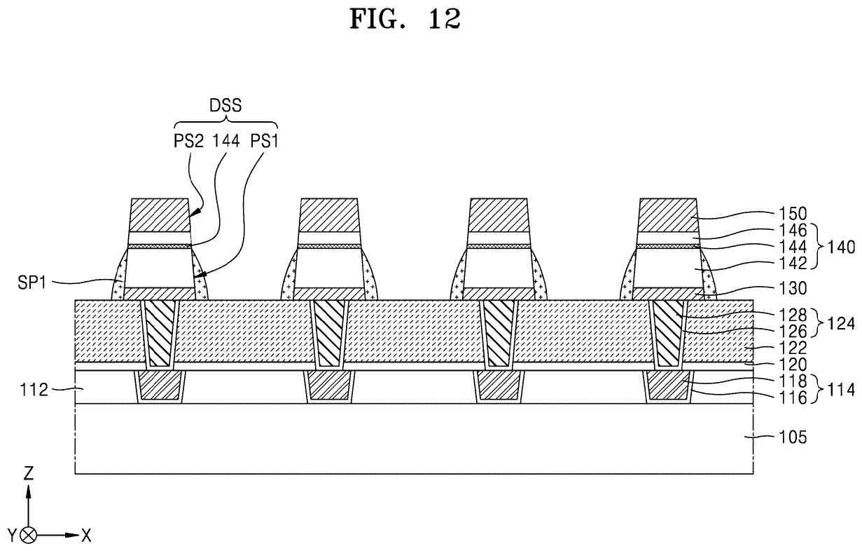

Referring to FIG. 11, with respect to a resultant structure of FIGS. 10A and 10B, a first spacer layer SL1 covering the second interlayer insulating layer 122 and each of the plurality of data storage structures DSS may be formed on the second interlayer insulating layer 122. For example, the first spacer layer SL1 may cover the upper surface and the side wall of each of the plurality of data storage structures DSS. According to some embodiments, the first spacer layer SL1 may be formed by using chemical vapor deposition (CVD) and/or atomic layer deposition (ALD). Specific materials included in the first spacer layer SL1 may be substantially the same as described with respect to the first lower spacer 162 described with reference to FIGS. 1 to 2E.

Referring to FIG. 12, with respect to a resultant structure of FIG. 11, a portion of the first spacer layer SL1 may be removed to form each of a plurality of first spacers SP1 respectively covering lower side walls of the plurality of data storage structures DSS. According to some embodiments, the first spacer layer SL1 may cover a side wall of the first pattern structure PS1. According to some embodiments, an uppermost surface of the first spacer layer SL1 may be located at substantially the same vertical level as a lower surface of the tunnel barrier pattern 144 or at a lower vertical level than the tunnel barrier pattern 144. According to some embodiments, each of the plurality of first spacers SP1 may be formed by removing a portion of the first spacer layer SL1 through anisotropic etching, without using an additional etch mask. For example, the etch process may include an RIE process.

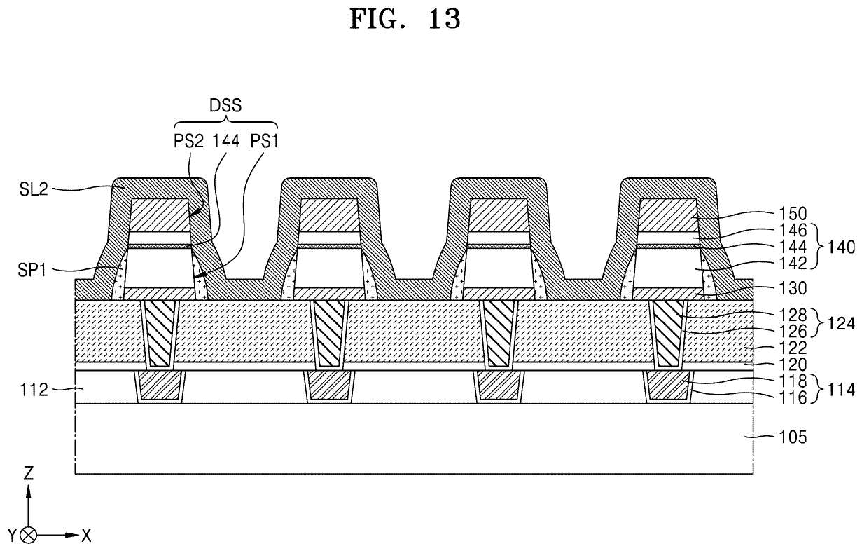

Referring to FIG. 13, with respect to a resultant structure of FIG. 12, a second spacer layer SL2 covering the second interlayer insulating layer 122, each of the plurality of data storage structures DSS, and each of the plurality of first spacers SP1 may be formed on the second interlayer insulating layer 122. For example, the second spacer layer SL2 may cover the upper surface and an upper side wall of each of the plurality of data storage structures DSS and an outer wall of each of the plurality of first spacers SP1. According to some embodiments, the second spacer layer SL2 may be formed by a CVD process and/or an ALD process. Specific materials included in the second spacer layer SL2 may be substantially the same as described with respect to the second lower spacer 164 and the first upper spacer 172 described with reference to FIGS. 1 to 2E.

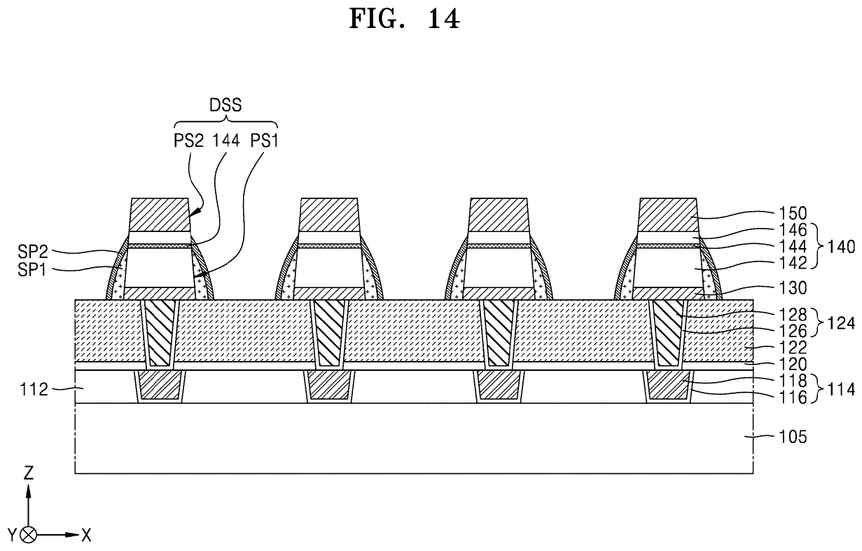

Referring to FIG. 14, with respect to a resultant structure of FIG. 13, a portion of the second spacer layer SL2 may be removed to form each of a plurality of second spacers SP2 respectively covering portions of the side walls of the plurality of data storage structures DSS and the outer walls of the plurality of first spacers SP1 respectively corresponding to the plurality of second spacers SP2. For example, an uppermost surface of each of the plurality of second spacers SP2 may be located at a higher vertical level than an uppermost surface of each of the plurality of first spacers SP1. For example, each of the plurality of first spacers SP1 may be covered by the second spacer SP2 corresponding thereto, from among the plurality of second spacers SP2, and may not be exposed.

According to some embodiments, each of the plurality of second spacers SP2 may cover the side wall 144S of the tunnel barrier pattern 144. According to some embodiments, each of the plurality of second spacers SP2 may cover at least a portion of the second magnetic pattern 146. According to some embodiments, an uppermost surface of each of the plurality of second spacers SP2 may be located at a higher vertical level than an upper surface of the tunnel barrier pattern 144.

According to some embodiments, each of the plurality of second spacers SP2 may be formed by removing a portion of the second spacer layer SL2 through anisotropic etching, without using an additional etch mask. For example, the etch process may include an RIE process.

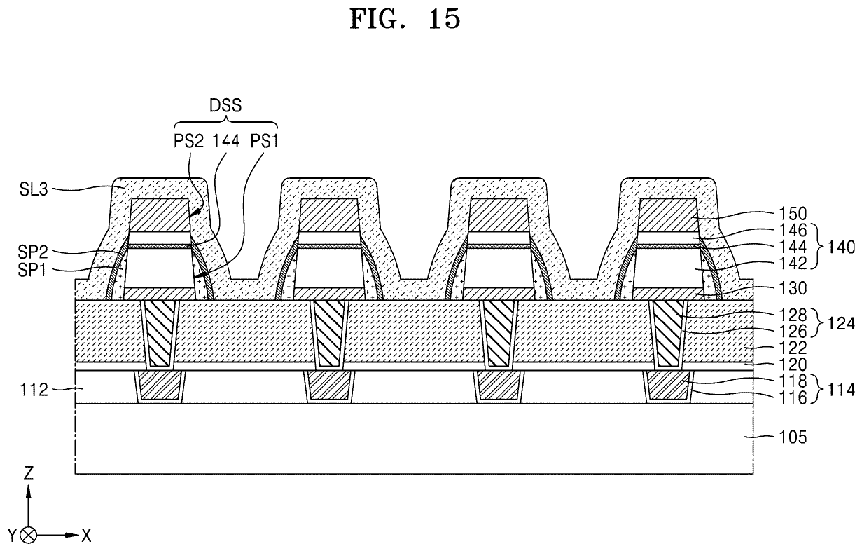

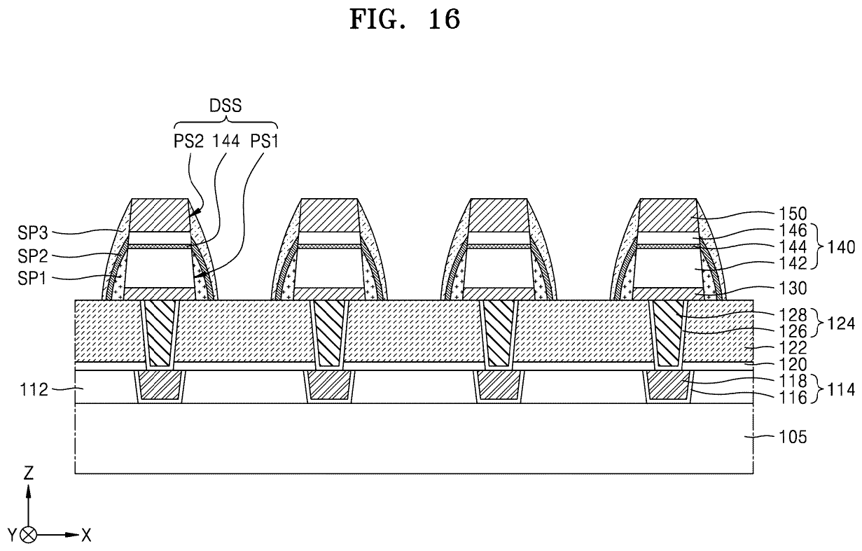

Referring to FIG. 15, with respect to a resultant structure of FIG. 14, a third spacer layer SL3 covering the second interlayer insulating layer 122, each of the plurality of data storage structures DSS, and each of the plurality of second spacers SP2 may be formed on the second interlayer insulating layer. For example, the third spacer layer SL3 may cover the upper surface and the upper side wall of each of the plurality of data storage structures DSS and an outer wall of each of the plurality of second spacers SP2. According to some embodiments, the third spacer layer SL3 may be formed through a CVD process and/or an ALD process. Specific materials included in the third spacer layer SL3 may be substantially the same as described with respect to the second upper spacer 174 described with reference to FIGS. 1 to 2E.

Referring to FIG. 16, with respect to a resultant structure of FIG. 15, a portion of the third spacer layer SL3 may be removed to form each of a plurality of third spacers SP3 respectively covering the upper side walls of the plurality of data storage structures DSS and the outer walls of the plurality of second spacer SP2 respectively corresponding to the plurality of third spacers SP3. According to some embodiments, each of the plurality of third spacers SP3 may cover a portion of the side wall of each of the plurality of data storage structures DSS, the portion not being covered by each of the plurality of first spacers SP1 and each of the plurality of second spacers SP2 and remaining. For example, each of the plurality of third spacers SP3 may cover a portion of a side wall of the second pattern structure PS2 on the corresponding second spacer SP2 from among the plurality of second spacers SP2. For example, the plurality of second spacers SP2 may be covered by the plurality of third spacers SP3, respectively, and may not be exposed.

Referring to FIGS. 17A and 17B, with respect to a resultant structure of FIG. 16, a low angle ion beam etch process may be performed to remove a portion of each of the plurality of first spacers SP1, a portion of each of the plurality of second spacers SP2, and a portion of each of the plurality of third spacers SP3, in order to form the first spacer structure 160 and the second spacer structure 170 covering the side wall of each of the plurality of data storage structures DSS.

In FIG. 17A, a direction of an ion beam IB is illustrated by an arrow. According to some embodiments, a beam angle θ_{B} formed by a first surface that is parallel to the upper surface 105U of the substrate 105 and the direction of the ion beam IB may have a relatively reduced angle compared to a general etch process in which an ion beam is incident in a direction (a Z direction) that is perpendicular to the first surface. According to some embodiments, the beam angle θ_{B} may be less than 60°, for example, less than 45°. The ion beam progresses at a relatively reduced angle, and thus, may easily remove a spacer covering some target layers of the magnetic tunnel junction structure 140, for example, a spacer covering the side wall 144S of the tunnel barrier pattern 144. Referring to FIG. 17B, a portion of the conductive re-deposition layer RD, the portion covering the side wall 144S of the tunnel barrier pattern 144, may be exposed through a space between the first spacer structure 160 and the second spacer structure 170.

According to some embodiments, the plurality of first spacers SP1, the plurality of second spacers SP2, and the plurality of third spacers SP3 may have different etch rates in an IBE process. According to some embodiments, the plurality of third spacers SP3 may have a lower etch rate than the plurality of first spacers SP1 and the plurality of second spacers SP2. According to some embodiments, the plurality of first spacers SP1 may have a lower etch rate than the plurality of second spacers SP2.

According to some embodiments, the plurality of first spacers SP1, the plurality of second spacers SP2, and the plurality of third spacers SP3 may have a reduced etch rate toward the upper surface 105U of the substrate 100, for example, as they are located at a reduced vertical level. For example, the plurality of first to third spacers SP1 to SP3 may have a relatively reduced etch rate as they are located at a reduced vertical level, due to a shadowing effect by the data storage structures DSS arranged around them.

Selective exposure of a portion of the spacer covering the side wall of the target layer by etching the plurality of first spacers SP1, the plurality of second spacers SP2, and the plurality of third spacers SP3 may be realized by the etch rate difference between the plurality of first to third spacers SP1 to SP3 and the shadowing effect described above. For example, the third spacer SP3 located at a relatively increased vertical level but having a relatively reduced etch rate may be slowly removed, and a portion of the second spacer SP2, the portion being covered by a relatively thin portion of the third spacer SP3, may be exposed through a low angle ion beam process. The exposed portion of the second spacer SP2 may be more quickly removed than the third spacer SP3, and the ion beam process may be performed until the portion covering the side wall 144S of the tunnel barrier pattern 144 is removed. Accordingly, a portion of the conductive re-deposition layer RD, the portion being arranged on the side wall 144S of the tunnel barrier pattern 144, may be exposed. For example, a portion of the first spacer SP1 may not be removed and may remain to form the first lower spacer 162, and a portion of the third spacer SP3 may not be removed and may remain to form the second upper spacer 174. For example, a portion of the second spacer SP2, the portion being located at a relatively increased vertical level, may be covered by the second upper spacer 174, may not be removed and may remain to form the first upper spacer 172. A portion of the second spacer SP2, the portion being located at a relatively decreased vertical level, may be relatively less removed due to a shadowing effect, so as to remain on an outer wall of the first lower spacer 162 to form the second lower spacer 164.

Thereafter, a process of oxidizing the exposed surface of the conductive re-deposition layer RD may be performed to form the isolation insulating layer DOL described with reference to FIGS. 2D and 2E. For example, a portion of the conductive re-deposition layer RD, the portion being covered by the first spacer structure 160, and a portion of the conductive re-deposition layer RD, the portion being covered by the second spacer structure 170, may not be oxidized and may form the first conductive re-deposition layer LRD and the second conductive-re-deposition layer URD, respectively. According to some embodiments, the oxidation process may include a natural oxidation process and a dry oxidation process.

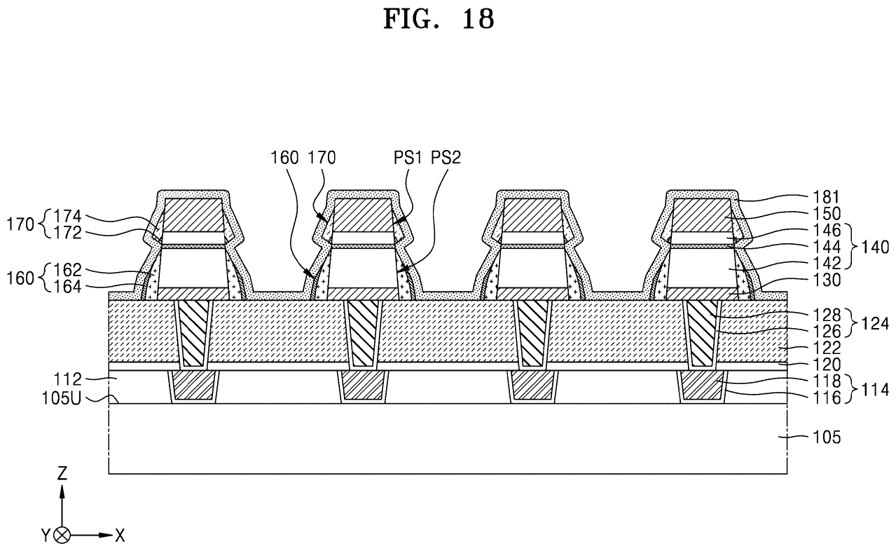

Referring to FIG. 18, with respect to a resultant structure of FIG. 17, the protective insulating layer 181 covering each of the plurality of data storage structures DSS, each of the first spacer structure 160, and each of the second spacer structure 170 may be formed. For example, the protective insulating layer 181 may be formed to cover an upper portion of each of the plurality of data storage structures DSS, an outer wall of each of the first spacer structure 160, an outer wall of each instance of the second spacer structure 170, and the isolation insulating layer DOL.

Referring to FIGS. 2A to 2E and FIG. 18, with respect to a resultant structure of FIG. 18, the gap-fill insulating layer 183 filling spaces between the plurality of data storage structures DSS may be formed on the protective insulating layer 181. Thereafter, a mask pattern (not shown) may be formed on the gap-fill insulating layer 183, and a portion of each of the gap-fill insulating layer 183 and the protective insulating layer 181 may be removed by using the mask pattern as an etch mask to form a plurality of second contact openings respectively exposing the upper surfaces of the plurality of data storage structures DSS. Thereafter, the contact barrier pattern 187 and the contact plug 189 filling each of the plurality of second contact openings may be formed to form each of the plurality of upper contact structures 185. Thereafter, the plurality of upper conductive lines 192 respectively connected to at least some of the plurality of upper contact structures 185 may be formed on the plurality of upper contact structures 185. Thereafter, the third interlayer insulating layer 194 filling the spaces between the plurality of upper conductive lines 192 may be formed to manufacture the magnetoresistive memory device 100.

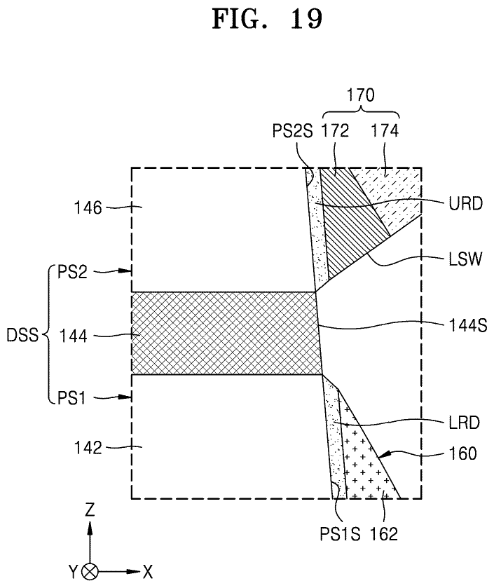

FIG. 19 is a cross-sectional view for describing a method of manufacturing a magnetoresistive memory device, according to some embodiments, and illustrates a region corresponding to the region indicated as “EXA2” of FIG. 2C. In FIG. 19, the same reference numerals as the reference numerals in FIGS. 1 to 2E and 6A and 6B refer to the same members as the members in FIGS. 1 to 2E and 6A and 6B, and their descriptions are not repeated here.

The process described above with reference to FIGS. 8 to 17B may be performed to form the plurality of data storage structures DSS and the first spacer structure 160 and the second spacer structure 170 provided on the side wall of each of the plurality of data storage structures DSS. Through the space between the first spacer structure 160 and the second spacer structure 170, a portion of the conductive re-deposition layer RD, the portion covering the side wall 144S of the tunnel barrier pattern 144, may be exposed.

Referring to FIG. 19, with respect to a resultant structure of FIGS. 17A and 17B, the exposed portion of the conductive re-deposition layer RD may be removed to expose the side wall 144S of the tunnel barrier pattern 144. Accordingly, a portion of the conductive re-deposition layer RD, the portion being covered by the first spacer structure 160, may not be removed and may remain to form the first conductive re-deposition layer LRD, and a portion of the conductive re-deposition layer RD, the portion being covered by the second spacer structure 170, may not be removed and may remain to form the second conductive re-deposition layer URD. According to some embodiments, in order to remove a portion of the conductive re-deposition layer RD, an IBE process or a wet etch process may be performed.

Thereafter, with respect to a resultant structure of FIG. 19, the insulating liner 180 covering the side wall 144S of the tunnel barrier pattern 144 may be formed. The insulating liner 180 may be formed, for example, by an ALD process. Thereafter, as described above with reference to FIG. 18, the protective insulating layer 181, the gap-fill insulating layer 183, the plurality of upper contact structures 185, and the plurality of upper conductive lines 192 may be formed to manufacture the magnetoresistive memory device 100d described with reference to FIGS. 6A and 6B.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination

While the disclosure has been particularly shown and described with reference to example embodiments thereof, it will be understood that various changes in form and details may be made therein without departing from the spirit and scope of the following claims.

What is claimed is:

1. A magnetoresistive memory device comprising:
a lower contact structure on a substrate;
a data storage structure comprising a first pattern structure, a tunnel barrier pattern, and a second pattern structure, wherein the first pattern structure, the tunnel barrier pattern, and the second pattern structure are sequentially stacked on the lower contact structure;
a first spacer structure covering a side wall of the first pattern structure;
a second spacer structure arranged apart from the first spacer structure in a vertical direction and covering a side wall of the second pattern structure;
an isolation insulating layer in contact with a side wall of the tunnel barrier pattern; and
a protective insulating layer covering the data storage structure, the first spacer structure, the second spacer structure, and the isolation insulating layer.

2. The magnetoresistive memory device of claim 1, further comprising:
a first conductive re-deposition layer arranged between the first pattern structure and the first spacer structure; and
a second conductive re-deposition layer arranged between the second pattern structure and the second spacer structure,
wherein the first conductive re-deposition layer is spaced apart from the second conductive re-deposition layer in the vertical direction, wherein the isolation insulating layer is arranged between the first conductive re-deposition layer and the second conductive re-deposition layer.

3. The magnetoresistive memory device of claim 1, wherein the first spacer structure comprises:
a first lower spacer provided on the side wall of the first pattern structure; and
a second lower structure covering an outer wall of the first lower spacer and spaced apart from the first pattern structure, wherein the first lower spacer is arranged between the first pattern structure and the second lower structure.

4. The magnetoresistive memory device of claim 3, wherein the second lower spacer covers a lower portion of the first lower spacer and does not cover an upper portion of the first lower spacer, and
the upper portion of the first lower spacer is in contact with the protective insulating layer.

5. The magnetoresistive memory device of claim 1, wherein an outer wall of the second spacer structure comprises:
a first portion arranged such that a horizontal thickness of the second spacer structure increases as a distance from an upper surface of the substrate becomes greater;
a second portion arranged such that the horizontal thickness of the second spacer structure decreases as the distance from the upper surface of the substrate becomes greater; and
a third portion at which the first portion and the second portion meet each other, wherein the horizontal thickness of the second upper spacer has a greatest value at the third portion.

6. The magnetoresistive memory device of claim 5, wherein a length of the first portion in the vertical direction is less than a length of the second portion in the vertical direction.

7. The magnetoresistive memory device of claim 5, wherein a first angle formed by the first portion and a first surface is less than a second angle formed by the second portion and the first surface, the first surface being parallel to the upper surface of the substrate.

8. The magnetoresistive memory device of claim 1, wherein the second spacer structure comprises:
a first upper spacer covering a lower portion of the side wall of the second pattern structure; and
a second upper spacer at least partially covering an upper portion of the side wall of the second pattern structure, wherein the second upper spacer is in contact with the first upper spacer.

9. The magnetoresistive memory device of claim 8, wherein the first upper spacer overlaps the second upper spacer in the vertical direction.

10. The magnetoresistive memory device of claim 8, wherein a distance between a lowermost surface of the second upper spacer and an upper surface of the substrate is greater than a distance between a lowermost surface of the first upper spacer and the upper surface of the substrate.

11. The magnetoresistive memory device of claim 8,
wherein an outer wall of the first upper spacer comprises:
a fourth portion arranged such that a horizontal thickness of the first upper spacer increases as a distance from an upper surface of the substrate becomes greater;
a fifth portion arranged such that the horizontal thickness of the first upper spacer decreases as a distance from the upper surface of the substrate becomes greater; and
a sixth portion at which the fourth portion and the fifth portion meet each other, wherein the horizontal thickness of the first upper spacer has a greatest value at the sixth portion, and
wherein the second upper spacer is in contact with the fifth portion of the first upper spacer and is not in contact with the fourth portion of the first upper spacer.

12. The magnetoresistive memory device of claim 11,
wherein an outer wall of the second spacer structure comprises:
a first portion arranged such that a horizontal thickness of the second spacer structure increases as a distance from an upper surface of the substrate becomes greater;
a second portion arranged such that the horizontal thickness of the second spacer structure decreases as the distance from the upper surface of the substrate becomes greater; and
a third portion at which the first portion and the second portion meet each other, wherein the horizontal thickness of the second spacer structure has a greatest value at the third portion, and
wherein the third portion of the second spacer structure is located farther from the upper surface of the substrate than the sixth portion of the first upper spacer.

13. The magnetoresistive memory device of claim 1, wherein the first spacer structure comprises a material different from a material included in the second spacer structure.

14. A magnetoresistive memory device comprising:
a lower contact structure on a substrate;
a data storage structure comprising a first pattern structure, a tunnel barrier pattern, and a second pattern structure, wherein the first pattern structure, the tunnel barrier pattern, and the second pattern structure are sequentially stacked on the lower contact structure;
a first spacer structure covering a side wall of the first pattern structure;
a second spacer structure arranged apart from the first spacer structure in a vertical direction and covering a side wall of the second pattern structure;
a first conductive re-deposition layer arranged between the first pattern structure and the first spacer structure;
a second conductive re-deposition layer arranged between the second pattern structure and the second spacer structure; and
an insulating liner in contact with a side wall of the tunnel barrier pattern between the first conductive re-deposition layer and the second conductive re-deposition layer, wherein the insulating liner covers an outer wall of the first spacer structure and an outer wall of the second spacer structure.

15. The magnetoresistive memory device of claim 14, wherein a horizontal thickness of the first spacer structure decreases as a distance from an upper surface of the substrate becomes greater.

16. The magnetoresistive memory device of claim 14, wherein the outer wall of the second spacer structure comprises:
a first portion arranged such that a horizontal thickness of the second spacer structure increases as a distance from an upper surface of the substrate becomes greater; and
a second portion arranged such that the horizontal thickness of the second spacer structure decreases as the distance from the upper surface of the substrate becomes greater.

17. The magnetoresistive memory device of claim 14,
wherein the first spacer structure comprises:
a first lower spacer provided on the side wall of the first pattern structure; and
a second lower structure covering an outer wall of the first lower spacer and spaced apart from the first pattern structure, wherein the first lower spacer is arranged between the second lower structure and the first pattern structure,
wherein the second spacer structure comprises:
a first upper spacer covering a lower portion of the side wall of the second pattern structure; and
a second upper spacer at least partially covering an upper portion of the side wall of the second pattern structure and in contact with the first upper spacer, and
wherein the first lower spacer comprises a material different from a material included in the second lower spacer, and the first upper spacer comprises a material different from a material included in the second upper spacer.

18. A magnetoresistive memory device comprising:
a lower contact structure on a substrate;
a data storage structure comprising a first pattern structure, a tunnel barrier pattern, and a second pattern structure, wherein the first pattern structure, the tunnel barrier pattern, and the second pattern structure are sequentially stacked on the lower contact structure;
a first spacer structure covering a side wall of the first pattern structure;
a second spacer structure arranged apart from the first spacer structure in a vertical direction and covering a side wall of the second pattern structure;
a first conductive re-deposition layer arranged between the first pattern structure and the first spacer structure;
a second conductive re-deposition layer arranged between the second pattern structure and the second spacer structure; and
an isolation insulating layer in contact with a side wall of the tunnel barrier pattern between the first conductive re-deposition layer and the second conductive re-deposition layer,
wherein a horizontal thickness of the first spacer structure decreases as a distance from an upper surface of the substrate becomes greater, and
wherein an outer wall of the second spacer structure comprises
a first portion arranged such that a horizontal thickness of the second spacer structure increases as a distance from the upper surface of the substrate becomes greater, and
a second portion arranged such that the horizontal thickness of the second spacer structure decreases as the distance from the upper surface of the substrate becomes greater.

19. The magnetoresistive memory device of claim 18,
wherein the first spacer structure comprises:
a first lower spacer provided on the side wall of the first pattern structure; and
a second lower structure covering an outer wall of the first lower spacer and spaced apart from the first pattern structure, wherein the first lower spacer is arranged between the second lower structure and the first pattern structure,
wherein the second spacer structure comprises:
a first upper spacer covering a lower portion of the side wall of the second pattern structure; and
a second upper spacer at least partially covering an upper portion of the side wall of the second pattern structure and in contact with the first upper spacer, and
wherein the first lower spacer comprises a material different from a material included in the second lower spacer, and the first upper spacer comprises a material different from a material included in the second upper spacer.

20. The magnetoresistive memory device of claim 19, wherein an outer wall of the first upper spacer comprises:
a fourth portion arranged such that a horizontal thickness of the first upper spacer increases as the distance from the upper surface of the substrate becomes greater;
a fifth portion arranged such that the horizontal thickness of the first upper spacer decreases as the distance from the upper surface of the substrate becomes greater; and
a sixth portion at which the fourth portion and the fifth portion meet each other, wherein the horizontal thickness of the first upper spacer has a greatest value at the sixth portion,
wherein the second upper spacer is in contact with the fifth portion of the first upper spacer and is not in contact with the fourth portion of the first upper spacer.
